(19) United States
(12) Patent Application Publication
(10) Pub. No.: US 2025/0115392 A1
(43) Pub. Date: Apr. 10, 2025

(54) STACKING SYSTEM

(71) Applicant: HANGZHOU GREAT STAR INDUSTRIAL CO., LTD., Hangzhou (CN)

(72) Inventor: Yueming LI, Hangzhou (CN)

(21) Appl. No.: 18/975,433

(22) Filed: Dec. 10, 2024

Related U.S. Application Data
(63) Continuation of application No. PCT/CN2024/122693, filed on Sep. 30, 2024.

(51) Int. Cl. B65D 21/02

(52) U.S. Cl. CPC B65D 21/0223; B65D 21/0204

(57) ABSTRACT

A stacking system is provided. The stacking system includes a first stacking device and a second stacking device. The first stacking device and the second stacking device are stacked along a Z direction, the first stacking device is provided with a first fitting structure. The second stacking device is provided with a second fitting structure. The first fitting structure and the second fitting structure both have a locked state and an unlocked state. The first fitting structure and the second fitting structure are capable of being locked with each other or being released from each other via a magnetic force.

### CROSS-REFERENCE TO RELATED APPLICATION

This application is a continuation of international patent application No. PCT/CN2024/122693, filed on Sep. 30, 2024. The content of the above identified application is hereby incorporated herein in its entirety by reference.

### TECHNICAL FIELD

The present disclosure relates to a field of stacking technology, and in particular, to a stacking system.

### BACKGROUND

Stacking is a good way to reduce space occupation, but simple stacking carries a risk of falling off. Therefore, a stacking method that can achieve locking during stacking and is easy to unlock for removal is required.

### SUMMARY

According to various embodiments of the present disclosure, a stacking system is provided.

The present disclosure provides a stacking system. The stacking system includes a first stacking device and a second stacking device. The first stacking device and the second stacking device are stacked along a Z direction. The first stacking device is provided with a first fitting structure. The second stacking device is provided with a second fitting structure. The first fitting structure and the second fitting structure both have a locked state and an unlocked state. When the first fitting structure and the second fitting structure are in the locked state, the first fitting structure and the second fitting structure are locked with each other to connect the first stacking device with the second stacking device. When the first fitting structure and the second fitting structure are in the unlocked state, the first fitting structure is capable of being released from the second fitting structure. The first fitting structure and the second fitting structure are capable of being locked with each other or being released from each other via a magnetic force.

Details of one or more embodiments of the present disclosure are presented in the attached drawings and descriptions below. And other features, purposes and advantages of the present disclosure will become apparent from the description, drawings and claims.

### BRIEF DESCRIPTION OF THE DRAWINGS

For a better description and illustration of embodiments and/or examples of those disclosures disclosed herein, reference may be made to one or more attached drawings. Additional details or examples used to describe the drawings should not be considered as limiting the scope of any of the disclosed disclosures, currently described embodiments and/or examples, and currently understood best modes of these disclosures.

FIG. 1 is a schematic diagram of a stacking system in one or more embodiments.

FIG. 2 is a side view of a stacking system in one or more embodiments.

FIG. 3 is a cross-sectional schematic view of the stacking system along A-A line in FIG. 2.

FIG. 4 is a partial cross-sectional schematic view of the stacking system along B-B line in FIG. 2.

FIG. 5 is a schematic diagram of a first stacking device in one or more embodiments.

FIG. 6 is a schematic diagram of a first stacking device in one or more embodiments.

FIG. 7 is a schematic diagram of a part of a stacking system in one or more embodiments.

FIG. 8 is a schematic diagram of a second stacking device in one or more embodiments.

FIG. 9 is a top view of a stacking system in one or more embodiments.

FIG. 10 is a cross-sectional schematic view of the stacking system along C-C line in FIG. 9.

FIG. 11 is a cross-sectional schematic view of a stacking system in one or more embodiments.

FIG. 12 is a partial cross-sectional schematic view of a stacking system in a locked state in one or more embodiments.

FIG. 13 is a partial cross-sectional schematic view of the stacking system in an unlocked state in FIG. 12.

FIG. 14 is a partial cross-sectional schematic view of a stacking system in a locked state in one or more embodiments.

FIG. 15 is a partial cross-sectional schematic view of the stacking system in an unlocked state in FIG. 14.

FIG. 16 is a partial cross-sectional schematic view of a stacking system in a locked state in one or more embodiments.

FIG. 17 is a partial cross-sectional schematic view of the stacking system in an unlocked state in FIG. 16.

FIG. 18 is a partial cross-sectional schematic view of a stacking system in a locked state in one or more embodiments.

FIG. 19 is a partial cross-sectional schematic view of the stacking system in an unlocked state in FIG. 18.

FIG. 20 is a partial cross-sectional schematic view of a stacking system in a locked state in one or more embodiments.

FIG. 21 is a partial cross-sectional schematic view of the stacking system in an unlocked state in FIG. 20.

FIG. 22 is a partial cross-sectional schematic view of a stacking system in a locked state in one or more embodiments.

FIG. 23 is a partial cross-sectional schematic view of the stacking system in an unlocked state in FIG. 22.

FIG. 24 is a partial cross-sectional schematic view of a stacking system in a locked state in one or more embodiments.

FIG. 25 is a partial cross-sectional schematic view of the stacking system in an unlocked state in FIG. 24.

FIG. 26 is a partial cross-sectional schematic view of a stacking system in a locked state in one or more embodiments.

FIG. 27 is a partial cross-sectional schematic view of the stacking system in an unlocked state in FIG. 26.

FIG. 28 is a partial cross-sectional schematic view of a stacking system in a locked state in one or more embodiments.

FIG. 29 is a partial cross-sectional schematic view of the stacking system in an unlocked state in FIG. 28.

FIG. 30 is a partial cross-sectional schematic view of a stacking system in a locked state in one or more embodiments.

FIG. 31 is a partial cross-sectional schematic view of the stacking system in an unlocked state in FIG. 30.

FIG. 32 is a partial cross-sectional schematic diagram of a stacking system in one or more embodiments.

FIG. 33 is a partial cross-sectional schematic view of the stacking system in another view in FIG. 32.

FIG. 34 is a partial cross-sectional schematic view of a stacking system in a locked state in one or more embodiments.

FIG. 35 is a partial cross-sectional schematic view of the stacking system in an unlocked state in FIG. 34.

FIG. 36 is a schematic diagram of a stacking system in a locked state in one or more embodiments.

FIG. 37 is a schematic diagram of the stacking system in an unlocked state in FIG. 36.

FIG. 38 is a partial cross-sectional schematic view of the stacking system along C-C line in FIG. 36.

FIG. 39 is a schematic diagram of a stacking system in a locked state in one or more embodiments.

FIG. 40 is a schematic diagram of the stacking system in an unlocked state in FIG. 39.

FIG. 41 is a partial cross-sectional schematic view of a stacking system in a locked state in one or more embodiments.

FIG. 42 is a partial cross-sectional schematic view of the stacking system in an unlocked state in FIG. 41.

FIG. 43 is a schematic diagram of a first fitting structure in one or more embodiments.

Reference signs are as follows: 100 represents a stacking system; 10 represents a first stacking device; 101 represents a limiting groove; 102 represents a moving groove; 1021 represents a second limiting portion; 20 represents a second stacking device; 21 represents an assembling hole; 211 represents a first fitting position; 212 represents a second fitting position; 22 represents a limiting protrusion; 30 represents a first fitting structure; 31 represent an first fitting component; 32 represents a first movable component; 3201 represents an assembly groove; 321 represents a seat; 322 represents a first snapping portion; 3221 represents a first guiding bevel; 323 represents a first actuation portion; 324 represents a locating block; 325 represents a first rotating shaft; 326 represents a first limiting portion; 33 represents a first elastic component; 34 represents a gear; 35 represents a transmission plate; 36 represents a third rotating shaft; 40 represents a second fitting structure; 41 represents a second fitting component; 42 represents a second snapping portion; 421 represents a second guiding bevel; 43 represents a stop portion; 44 represents a second movable component; 4401 represents an installing hole; 441 represents a second actuation portion; 442 represents an applying-force end; 443 represents a second rotating shaft; 45 represents a locating assembly; 451 represents a second elastic component; 452 represents a ball bearing; 46 represents a third elastic component; 47 represents a fourth elastic component; 50 represents a third fitting structure; 60 represents a fourth fitting structure; 70 represents an electrical component; 71 represents a controlling module; 711 represents a controlling switch; 712 represents an operation screen; 72 represents a wireless communication module; 73 represents a remote operation module; and 74 represents a display module.

### DETAILED DESCRIPTION

The technical scheme in the embodiment of the present disclosure will be described clearly and completely with the attached drawings. Obviously, the described embodiment is only a part of the embodiment of the present disclosure, not the whole embodiment. Based on the embodiments in the present disclosure, all other embodiments obtained by ordinary technicians in this field without creative work belong to the protection scope of the present disclosure.

It should be noted that, when a member is considered “fixed on” or “set on” another member, it can be directly fixed on another member or there may be a centered member present simultaneously. When a member is considered “connected to” another member, it can be directly connected to another member or there may be a centered member present simultaneously. The terms “vertical”, “horizontal”, “left”, “right” and similar expressions used in the specification of the present disclosure are for illustrative purposes only and do not represent the only implementation method.

In addition, the terms “first” and “second” are only used to describe the purpose and can not be understood as indicating or implying relative importance or implying the quantity of indicated technical features. Therefore, the features limited to “first” and “second” can explicitly or implicitly include at least one of these features. In the description of the present disclosure, “multiple” means at least two, such as two, three, etc., unless there is an otherwise specific limitation.

In the present disclosure, unless there is the otherwise specifications and limitations, the first feature is “above” or “below” the second feature which may be a direct contact between the first and second features, or the first features and the second features may be in indirect contact through an intermediate medium. Moreover, the first feature is “on”, “above”, and “over” the second feature can be that the first feature is directly or diagonally above the second feature, or only indicates that the first feature is horizontally higher than the second feature. The first feature is “beneath”, “below”, and “under” the second feature can be that the first feature is directly or diagonally below the second feature, or only indicate that the horizontal height of the first feature is less than that of the second feature.

Unless otherwise defined, all technical and scientific terms used in this article have the same meanings as those commonly understood by those skilled in the art of the present disclosure. The terms used in the specification of the present disclosure are only for the purpose of describing specific embodiments and are not intended to limit the present disclosure. The term “and/or” used in this article includes any and all combinations of one or more related listed items.

Stacking is a good way to reduce space occupation, but simple stacking carries a risk of falling off. Therefore, a stacking method that can achieve both stack locking and easy unlocking and retrieval is required.

In related technology, a stacking system is required to remain a unlock state while taking a stacking component when the stacking system is taken. When a weight of the stacking component is great, the above operation is inconvenient and involves a certain lever of security risk.

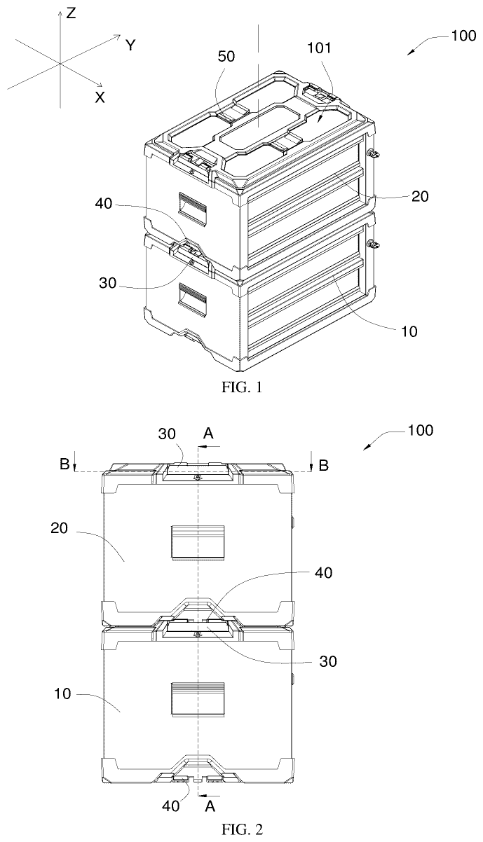

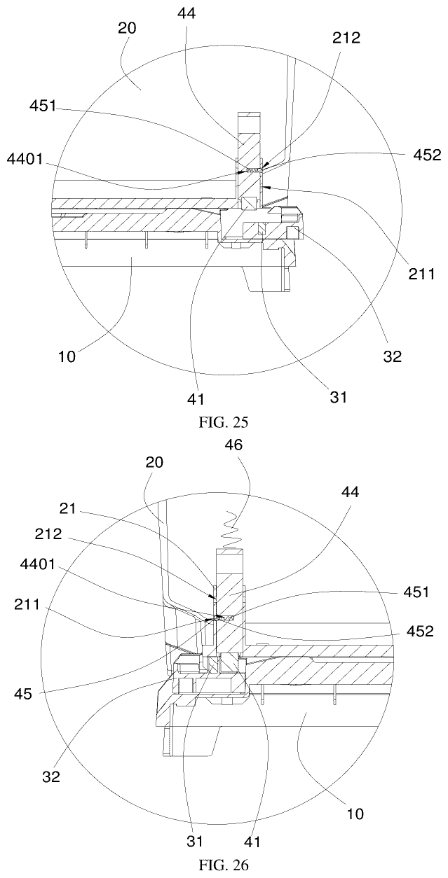

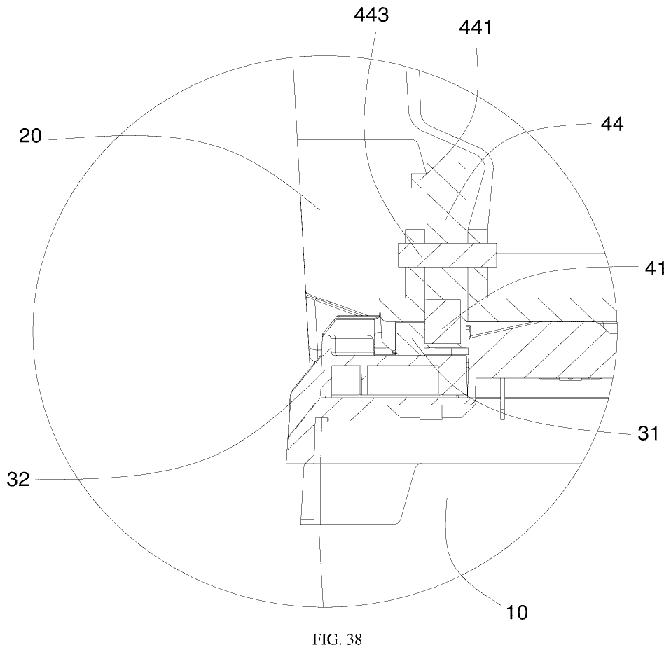

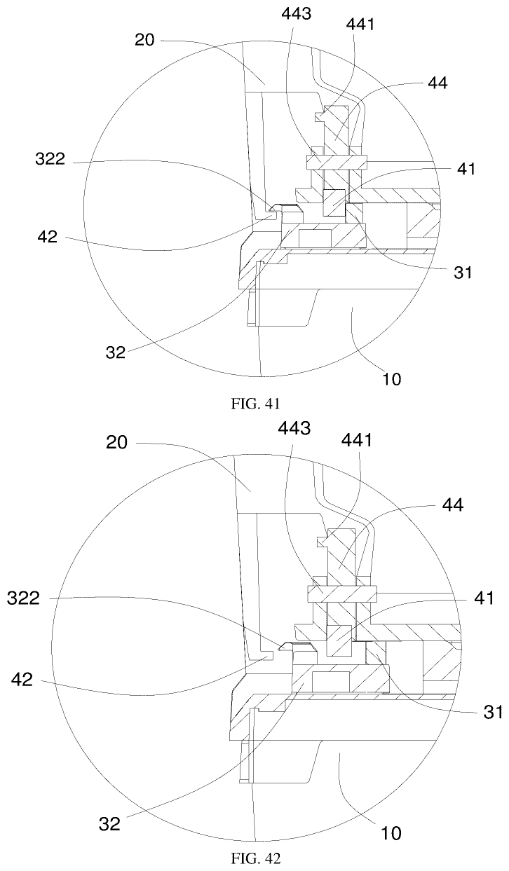

Referring to FIGS. 1 to 43, in order to solve a problem of inconvenient operation when unlocking and picking up the traditional stacking systems, the present disclosure provides a stacking system 100, the stacking system 100 can be applied in fields such as storing, transporting and so on.

In the following embodiments, an X direction, a Y direction and a Z direction correspond to three three-dimensional directions of the stacking system 100. But the X direction, Y direction and Z direction in the present disclosure are not limited by performances in the embodiments.

Referring to FIGS. 1 to 11, the stacking system 100 in the present disclosure includes a first stacking device 10 and a second stacking device 20. The first stacking device 10 is stacked on the second stacking device 20 along the Z direction. The first stacking device 10 is provided with a first fitting structure 30. The second stacking device 20 is provided with a second fitting structure 40. The first fitting structure 30 and the second fitting structure 40 both have a locked state and an unlocked state. When the first fitting structure 30 and the second fitting structure 40 are in the locked state, the first fitting structure 30 and the second fitting structure 40 are locked with each other to connect the first stacking device 10 with the second stacking device 20. When the first fitting structure 30 and the second fitting structure 40 are in the unlocked state, the first fitting structure 30 is capable of being released from the second fitting structure 40. The first fitting structure 30 and the second fitting structure 40 are capable of being locked with each other or being released from each other via a magnetic force.

The present disclosure provides the first fitting structure 30 and the second fitting structure 40, the first stacking device 10 is effectively connected to the second stacking device 20 by cooperation between the first fitting structure 30 and the second fitting structure 40, thereby improving stability of the stacking system 100 when the stacking system 100 is stacked, which may fully utilize a storage space and ensure stability of transporting and safety after the stacking system 100 being stacked.

In an embodiment, the first fitting structure 30 and the second fitting structure 40 are at a locked position when being in the locked state and at a released position when being in the unlocked state. The first fitting structure 30 and the second fitting structure 40 are positioned at the released position and/or the locked position via the magnetic force. The first fitting structure 30 and the second fitting structure 40 are locked at the released position through the magnetic force, such that at least part of the first stacking device 10 may be released and separated from the second stacking device 20. After the first stacking device 10 being separated from the second stacking device 20, and when an effect of magnetic force between the first fitting structure 30 and the second fitting structure 40 is reduced or disappeared, at least one of the first fitting structure 30 and the second fitting structure 40 may be reset at the locked position. When the first stacking device 10 is stacked with the second stacking device 20 through gravity of the first stacking device 10 or an external force, the first fitting structure 30 is automatically locked with the second fitting structure 40. Therefore, overall cooperation between the first stacking device 10 and the second stacking device 20 is simpler, thereby greatly improving an operation efficiency.

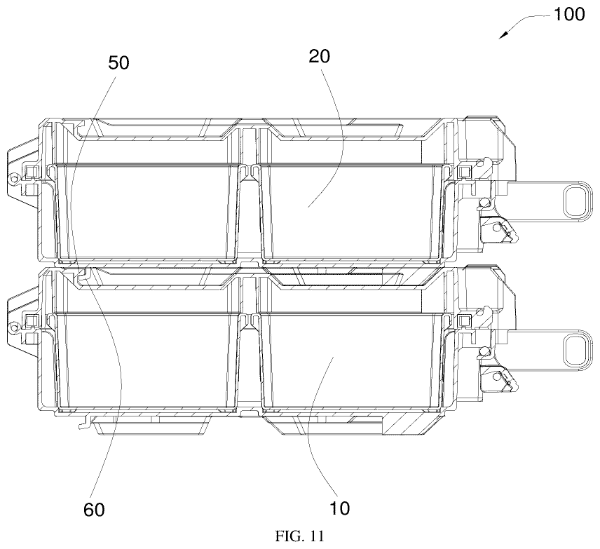

The number of the first stacking device 10 can be one or more, and the number of the second stacking device 20 can be one or more, which can be set as required. For example, it takes that the first stacking device 10 is located on bottom and the second stacking device 20 is located on top as an example to illustrate. The first stacking device 10 and the second stacking device 20 can be both configured as rectangular-case-shaped or box-shaped structures with the same size and structure as shown in FIGS. 1 and 11. Alternatively, the first stacking device 10 and the second stacking device 20 can be configured as other shapes such as prisms, cylinders, and so on. In addition, the size of the first stacking device and the second stacking device may be different as shown in FIGS. 7 to 12. When the size of the first stacking device 10 is different from that of the second stacking device 20, a length of the first stacking device 10 may be set to be an integer multiple of a length of the second stacking device 20, facilitating the first stacking device 10 fitting with the second stacking device 20.

In order to improve reliably of stacked connection between the first stacking device 10 and the second stacking device 20, in an embodiment, as shown in FIGS. 2, 3, 9, 10 and 11, the first stacking device 10 is further provided with a third fitting structure 50. The third fitting structure 50 is disposed on a positive side of the first stacking device 10 relative to the first fitting structure along the Y direction or the X direction. The second stacking device 20 is further provided with a fourth fitting structure 60. The fourth fitting structure 60 is disposed on a positive side of the second stacking device 20 relative to the second fitting structure along the Y direction or the X direction. The third fitting structure 50 fits with and is connected to the fourth fitting structure 60. When the third fitting structure 50 fits with the fourth fitting structure 60 and the first fitting structure 30 fits with the second fitting structure 40, a movement of the first stacking device 10 and the second stacking device 20 is restricted at least along the Z direction.

Cooperation between the third fitting structure 50 and the fourth fitting structure 60 is combined with cooperation between the first fitting structure 30 and the second fitting structure 40, which may ensure two opposite sides of the first stacking device 10 can be connected to two opposite sides of the second stacking device 20, respectively, thereby restricting a movement of the first stacking device 10 and the second stacking device 20 at least along the Z direction.

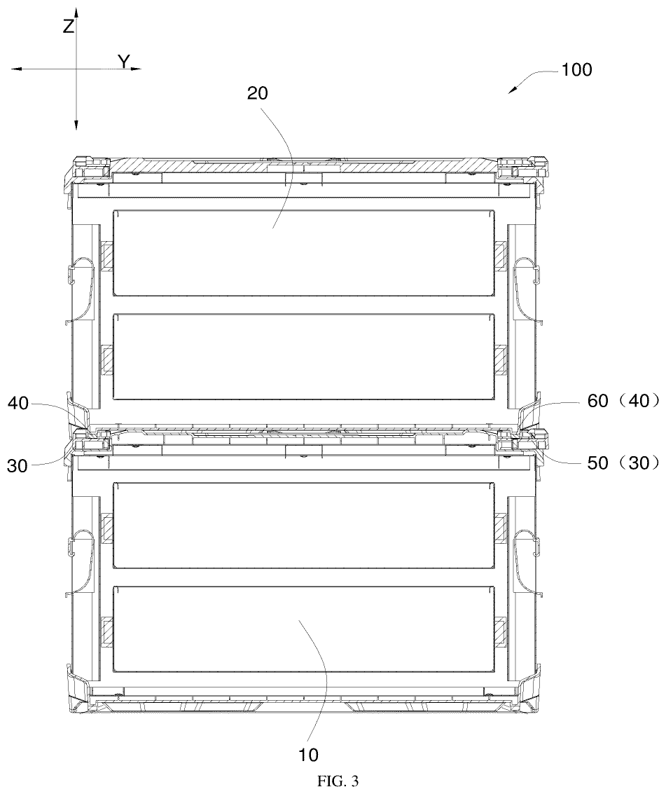

Referring to FIG. 3, the third fitting structure 50 can be the same as the first fitting structure 30. The fourth fitting structure 60 can be the same as the second fitting structure. Therefore, cooperation between the third fitting structure 50 and the fourth fitting structure 60 can be firmer, which can adapt the first stacking device 10 and the second stacking device 20 having a greater inner space and carrying capacity.

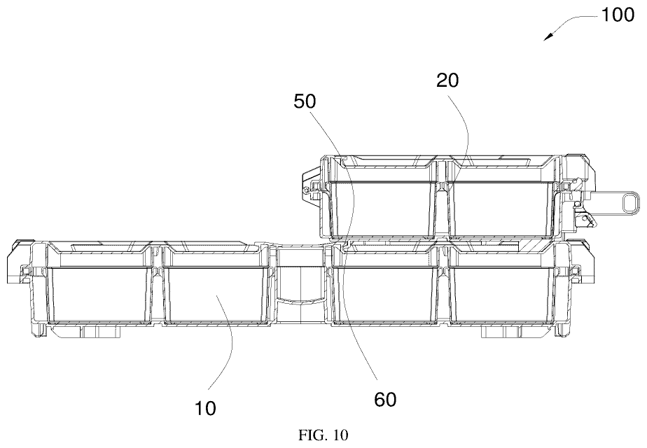

Alternatively, the third fitting structure 50 may be different from the fourth fitting structure 60. For example, referring to FIGS. 10 and 11, one of the third fitting structure 50 and the fourth fitting structure 60 is configured as a hook, and the other one of the third fitting structure 50 and the fourth fitting structure 60 is configured as a groove. The hook is inserted into the groove to restrict movement of the second stacking device 20 at least along the Z direction. Therefore, the cooperation between the third fitting structure 50 and the fourth fitting structure 60 are simpler, thereby greatly improving efficiency of locking the first stacking device 10 with the second stacking device 20 or releasing the first stacking device 10 from the second stacking device 20.

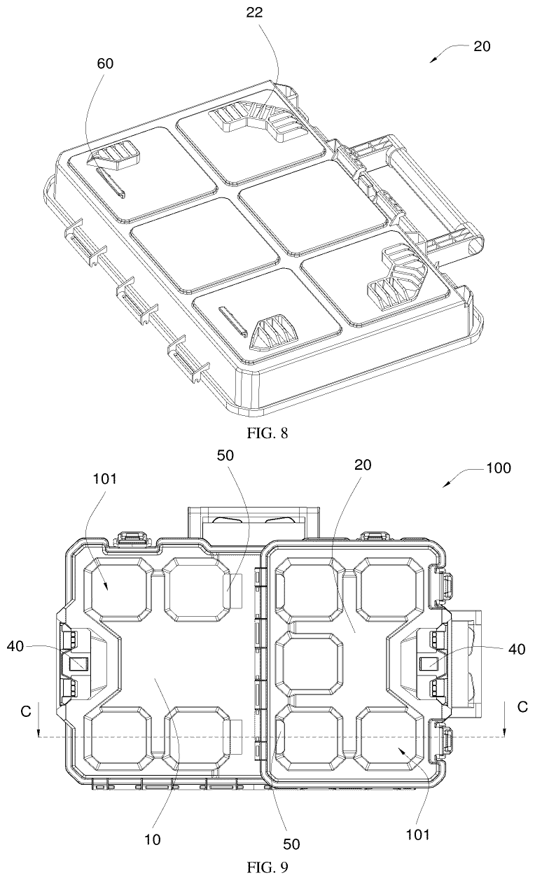

In order to restrict movement of the first stacking device 10 relative to the second stacking device 20 along the X direction and the Y direction, in an embodiment, referring to FIGS. 8 and 9, one of the first stacking device 10 and the second stacking device 20 protrudes to form a limiting protrusion 22 along the Z direction, and the other of the first stacking device 10 and the second stacking device 20 is recessed to form the limiting groove 101 along the Z direction. The limiting protrusion 22 is inserted into the limiting groove 101. Therefore, the first stacking device 10 and the second stacking device 20 are more stable and reliable when the first stacking device 10 is stacked with and locked with the second stacking device 20.

In the present disclosure, the limiting protrusion 22 is disposed on the second stacking device 20. The limiting groove 101 is disposed on the first stacking device 10.

The present disclosure takes that the third fitting structure 50 is the same as the first fitting structure 30 and the fourth fitting structure 60 is the same as the second fitting structure 40 as an example to illustrate. In order to realize a stacking effect of the stacking system 100, the second fitting structure 40 and the fourth fitting structure 60 are disposed on a bottom of the second stacking device 20, and the first fitting structure 30 and the third fitting structure 50 are disposed on a top of the second stacking device 20.

In an embodiment, the first fitting structure 30 includes a first fitting component 31, the second fitting structure 40 includes a second fitting component 41, and the first fitting component 31 fits with the second fitting component 41 via magnetic attraction or magnetic repulsion. Therefore, the first fitting structure 30 can be locked with or released from the second fitting structure 40 by different magnetic-fitting manners.

Furthermore, in an embodiment, one of the first fitting structure 30 and the second fitting structure 40 is provided with a magnet, and the other of the first fitting structure 30 and the second fitting structure 40 is provided with a ferromagnet, i.e., one of the first fitting component 31 and the second fitting component 41 is configured as the magnet, and the other of the first fitting component 31 and the second fitting component 41 is configured as the ferromagnet. Therefore, the first fitting component 31 can fit with the second fitting component 41 via magnetic attraction.

The magnet is defined as an objection that can generate magnetic field. The ferromagnet is defined as an objection having ferromagnetism, which can attract by the magnetic field. The ferromagnet can be generally made of iron, cobalt, nickel, alloy and so on. Alternatively, the ferromagnet can be made of a polymer composite material including iron, cobalt, nickel, alloy and so on, such as a iron plastic component and so on.

In another embodiments, the first fitting structure 30 and the second fitting structure 40 can be both provided with a magnet, i.e., the first fitting component 31 and the second fitting component 41 are all configured as the magnet body. Therefore, the first fitting component 31 fits with the second fitting component 41 via magnetic attraction or magnetic repulsion.

In other embodiments, the first fitting structure 30 and/or the second fitting structure 40 can be both provided with an electromagnet, i.e., the first fitting component 31 and/or the second fitting component 41 are configured as the electromagnet, and the first fitting component 31 and/or the second fitting component 41 generates magnetism by energizing, such that the first fitting component 31 can fit with the second fitting component 41 more flexibly. The first fitting component 31 and the second fitting component 41 are both configured as the electromagnet that is taken as an example to illustrate herein. Correspondingly, the stacking system 100 is provided with a correspondingly electrical component 70.

For example, the first fitting component 31 and the second fitting component 41 can generate magnetic attraction by applying an electric current, and the first fitting structure 30 and the second fitting structure 40 can directly attract with each other by a strong magnetic effect between the first fitting component 31 and the second fitting component 41, thereby locking the first fitting structure 30 with the second fitting structure 40. When the first fitting structure 30 is required to be released from the second fitting structure 40, magnetic attraction between the first fitting component 31 and the second fitting component 41 is disappeared by cutting off power, thereby releasing the first fitting structure 30 from the second fitting structure 40.

In an embodiment, the stacking system 100 further includes a controlling module 71, the controlling module 71 is signal-connected to the first fitting component 31, which is configured for controlling a magnetic state and a non-magnetic state of the first fitting component 31. Alternatively, the controlling module 71 is signal-connected to the second fitting component 41, which is configured for controlling a magnetic state and a non magnetic state of the second fitting component 41.

Therefore, it is conducive to controlling magnetism of the first fitting component 31 and/or the second fitting component 41.

In the present disclosure, the controlling module 71 includes a controlling switch 711. Alternatively, the controlling module 71 may include an operation screen 712. Therefore, it is conducive to manual operation, thereby significantly improving convenience of controlling the first fitting component 31 and the second fitting component 32. The controlling switch 711 and the operation screen 712 can be reasonably arranged according to a space requirement.

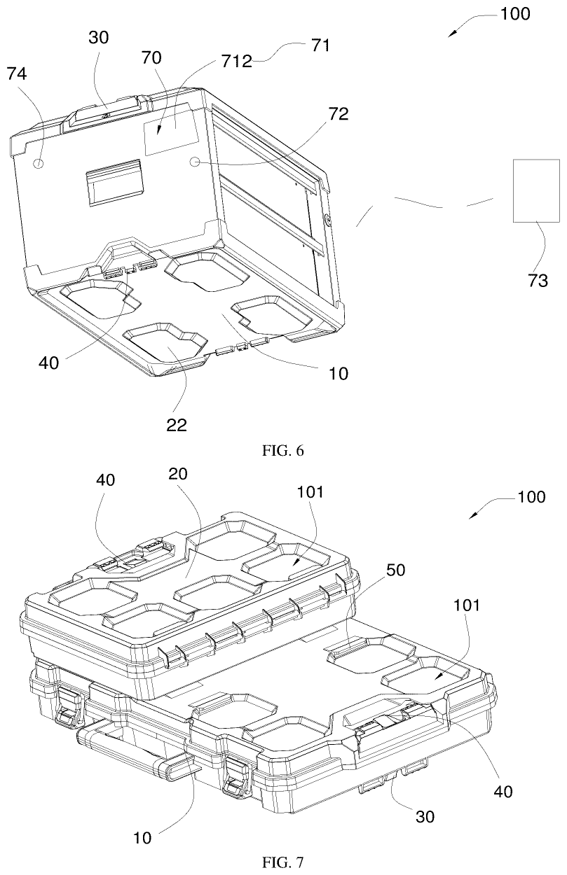

For example, referring to FIG. 5, the first fitting structure 30 can be provided with a controlling switch 711 to control the magnetic state and the non-magnetic state of the first fitting component 31. Alternatively, referring to FIG. 6, the first stacking device 10 is provided with an operation screen 712 to control the magnetic state and the non-magnetic state of the second fitting component 41.

Furthermore, in an embodiment, referring to FIG. 6, the stacking system 100 further includes a wireless communication module 72 and a remote operation module 73. The wireless communication module 72 is disposed on the first stacking device 10 and/or the second stacking device 20. The wireless communication module is signal-connected to the controlling module 71 and the remote operation module 73. Therefore, the stacking system 100 can be switched between the locked state and the unlocked state by an electronic remote control, thereby further improving convenience of the stacking system 100.

The wireless communication module 72 can be configured as wireless WiFi, Bluetooth, cellular network, satellite communication, NFC, mobile communication technology, long-distance wireless broadcasting and so on, which is not limited herein.

In an embodiment, referring to FIG. 6, the stacking system 100 further includes a display module 74. The display module 74 is configured to indicate that the stacking system 100 is in the locked state or the unlocked state. Therefore, the locked state and the unlocked state of the stacking system 100 is more visual to reduce probability of operational errors, thereby preventing the first stacking device 10 and the second stacking device 20 from damaging.

For example, the display module 74 can be configured as a pilot lamp. For example, when the stacking system 100 is in the locked state, the pilot lamp emits a red light, and when the stacking system 100 is in the unlocked state, the pilot lamp emits a green light. Alternatively, a light of the pilot lamp can be configured as other colors, as long as the light of the pilot lamp can play a same role of indication.

In the present disclosure, a first embodiment of cooperation between the first fitting structure 30 with the second fitting structure 40 will be introduced hereinafter.

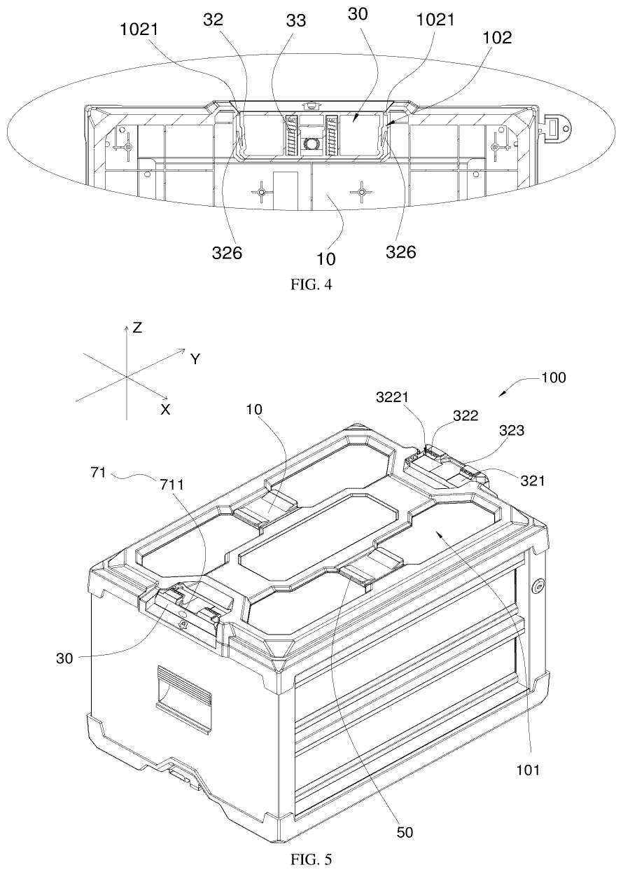

Referring to FIGS. 3 and 4, in an embodiment, the first fitting structure 30 further includes a first movable component 32. The first movable component 32 is movably connected to the first stacking device 10. The first fitting component 31 is mounted in the first movable component 32. This is, in the present disclosure, the first movable component 32 may drive the first fitting component 31 to move, thereby realizing locking the first fitting structure 30 with the second fitting structure 40 or releasing the first fitting structure 30 from the second fitting structure 40.

In order to further improve the convenience of the stacking system 100, in an embodiment, referring to FIG. 4, the first fitting structure 30 further includes a first elastic component 33. The first elastic component 33 is connected to the first movable component 32 and the first stacking device 10, respectively, thereby applying a force to the first movable component 32. An elastic force of the first elastic component 33 can be cooperated with a magnetic force between the first fitting component 31 and the second fitting component 41, an external forced and so on, thereby realizing locking the first stacking device 10 with the second stacking device 20 or releasing the first stacking device 10 from the second stacking device 20. For example, during a stacking process, when the second stacking device 20 is stacked on the first stacking device 10, the second stacking device 20 is only required to be directly disposed on the first stacking device 10. The second stacking device 20 may automatically be in the locked state relying on gravity of the second stacking device 20, thereby reducing difficulty of a locking operation, facilitating improving working efficiency and convenience of stacking and positioning the second stacking device 20 with the first stacking device 10. It will takes that the first fitting structure 30 includes the first elastic component 33 as an example to illustrate. When no first elastic component 33 is provided, the first movable component 32 can be moved by a manual manner.

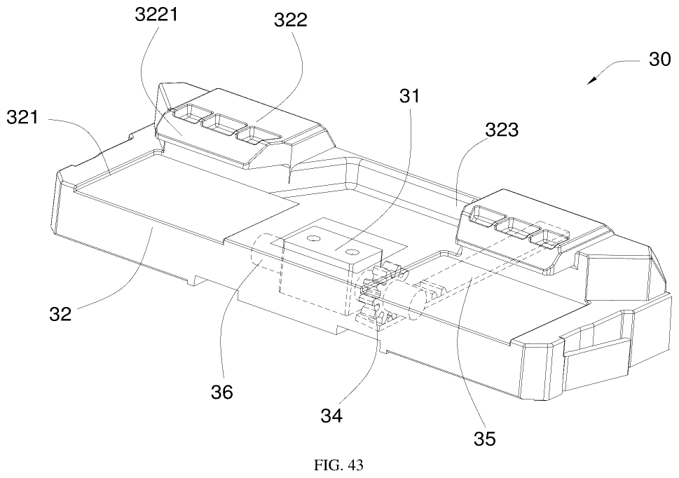

Furthermore, in an embodiment, referring to FIGS. 5 and 43, the first movable component 32 includes a seat 321 and a first snapping portion 322 disposed on the seat 321. The seat 321 can be movably connected to the first stacking device 10. The second fitting structure 40 includes a second snapping portion 42 disposed on the second stacking device 20. The first snapping portion 322 can be inserted into and snapped with the second snapping portion 42 to form the locked state. Therefore, snap between the first snapping portion 322 and the second snapping portion 42 is simple, which may ensure an effect of snapping, thereby realizing stacking and limiting the first stacking device 10 with the second stacking device 20.

The first snapping portion 322 can be configured as a snapping plate, the second snapping portion 42 can be correspondingly provided with a snapping groove. The snapping plate can correspond to the snapping groove one by one. Alternatively, one snapping groove can be snapped with a plurality of snapping plates. The second snapping portion can be recessed to define the snapping groove herein. Alternatively, the second snapping portion 42 can be configured as a hook and so on, and the snapping groove is defined by a space where the hook bends.

A position and a snapping direction of the first snapping portion 322 and the second snapping portion 42 can be reasonably provided according to a movement direction of the first movable component 32, which is described in detail as following. A snapping direction between the first fitting structure 30 and the second fitting structure 40 can be provided to be opposite to a snapping direction between the third fitting structure 50 and the fourth fitting structure 60, which is conducive to avoiding failing to snap the third fitting structure 50 with the fourth fitting structure 60.

Furthermore, in an embodiment, referring to FIG. 4, the first stacking device 10 is provided with a moving groove 102. The seat 321 is movably mounted in the moving groove 102. Two sidewalls of the moving groove 102 opposite to each other is provided with a second limiting portion 1021. Correspondingly, the first movable component 32 further includes a first limiting portion 326 connected to two sidewalls of the seat 321 opposite to each other. The first limiting portion 326 can fit with the second limiting portion 1021 to restrict a moving or rotating range of the first movable component 32, and preventing the first movable component 32 from detaching from the moving groove 102.

The second limiting portion 1021 can be configured as a protrusion structure protruding from a sidewall of the moving groove 102. The first limiting portion 326 can be configured as an elastic reverse clamping structure, facilitating mounting the first limiting portion 32.

The first movable component 32 can be conducive to automatically moving by the gravity of the second stacking device 20 when the first stacking device 10 is stacked with the second stacking device 20. In an embodiment, referring to FIG. 43, the first snapping portion 322 is provided with a first guiding bevel 3221, and the first guiding bevel 3221 is disposed on an end of the first snapping portion 322 towards the second snapping portion 42.

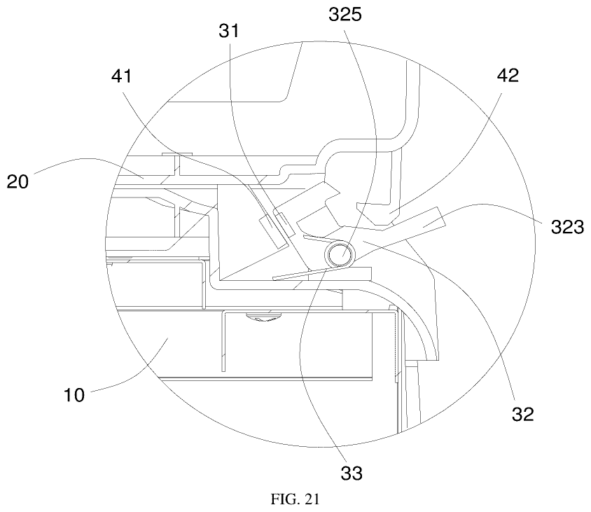

Furthermore, in an embodiment, referring to FIG. 20, the second snapping portion 42 is provided with a second guiding bevel 421. The second guiding bevel 421 is disposed on an end of the second snapping portion 42 towards the first snapping portion 322. Therefore, when the second stacking device 20 is disposed on the first stacking device 10, the first snapping portion 322 fits with the second snapping portion 42 more smoothly, such that the first stacking device 10 can be quickly locked with the second stacking device 20.

In order to improve reliably of snapping the first snapping portion 322 with the second snapping portion 42, in an embodiment, the number of the first snapping portion 322 is two, and two first snapping portions are separated from each other. Alternatively, the number of the first snapping portion can be one or more, which can be set as required.

In an embodiment, referring to FIG. 43, the first movable component 32 further includes a first actuation portion 323. The first actuation portion 323 is connected to the seat 321. The first actuation portion 323 is configured to provide a force position to slide or rotate the first movable component 32. Therefore, it is conducive for an operator pulling or pushing the first movable component 32.

The first actuation portion 323 can be provided as any one of a protrusion, a groove or a knurling.

Furthermore, in an embodiment, two or three of the seat 321, the first snapping portion 322 and the first actuation portion 323 can be configured as an integrated structure, facilitating processing and improving strength of the first movable component 32.

Referring to FIGS. 12 to 23, in the present disclosure, the second fitting component 41 is disposed on the second stacking device 20, and the first fitting component 31 fits with the second fitting component 41 via magnetic attraction. This is, in the present disclosure, a position between the second fitting component 41 and the second stacking device 20 substantially remains. Therefore, in the present disclosure, the first movable component 32 is required to be moved by the external force to realize releasing the first stacking device 10 from the second stacking device 20.

Furthermore, referring to FIGS. 12 to 23, the first movable component 32 is slidably connected to the first stacking device 10 along the Y direction. The first fitting component 31 fits with the second fitting component 41 via magnetic attraction along the Z direction. The first fitting component 31 can fit with the second fitting component 41 in the locked state or the unlocked state via magnetic attraction herein.

When the first fitting component 31 fits with the second fitting component 41 in the locked state via magnetic attraction, the first fitting structure 30 and the second fitting structure 40 can be positioned by the first fitting component 31 and the second fitting component 41 via magnetic attraction in the locked state. The first elastic component 33 deforms and remains deformation. The first elastic component 33 has a tendency of driving the first snapping portion 322 to move away from the second snapping portion 42. When the first fitting structure 30 is required to be released from the second fitting component 41, the first movable component 32 can be moved by the external force, such that the first fitting component 31 can be misaligned with the second fitting component 41. The first elastic component 33 can enable the first movable component 32 to automatically move, which can save more time and labor. Alternatively, when the first fitting component 31 and the second fitting component 41 are provided with an electromagnet, a magnetic force of the first fitting component 31 or the second fitting component 41 can disappear, such that the first movable component 32 can move to automatically release the first fitting structure 30 from the second fitting structure 40.

When the first fitting component 31 fits with the second fitting component 41 in the unlocked state via magnetic attraction, the first fitting component 31 is misaligned with the second fitting component 41 in the locked state. A magnetic attraction between the first fitting component 31 and the second fitting component 41 is not sufficient. Therefore, the first elastic component 33 can apply a force to the first movable component 32 to enable the first snapping portion 322 to insert into the second snapping portion 42, thereby snapping the first snapping portion 322 with the second snapping portion 42. When the first fitting component 31 is required to be released from the second fitting component 41, the first movable component 32 can be suffered from the external force to move to a position, such that the first fitting component 31 can fit with the second fitting component at a corresponding position via magnetic attraction. The first elastic component 33 deforms and remains deformation via magnetic attraction. The first elastic component 33 has a tendency of driving the first elastic component 33 to move towards the second snapping portion 42. The first fitting structure 30 and the second fitting structure 40 can be positioned by the first fitting component 31 and the second fitting component 41 via magnetic attraction, preventing the first movable component 32 from moving and resetting by the elastic force of the first elastic component 33, such that the first stacking device 10 and the second stacking device 20 are in the unlocked state. Therefore, in the unlocked state, the first movable component 32 is not required to be controlled, and the second stacking device 20 can be separated from the first stacking device 10 by directly taking the second stacking device 20, an operation thereof is easy. After detaching the second stacking device 20 from the first stacking device 10, magnetic attraction between the first fitting component 31 and the second fitting component 41 disappears due to a distance between the first fitting component 31 and the second fitting component 41 being so far, and the first movable component 32 can be automatically reset via the elastic force of the first elastic component 33, the overall operation is easier.

The first movable component 32 can slide towards or away from a center of the first stacking device 10 along the Y direction, thereby releasing the first snapping portion 322 from the second snapping portion 42.

In order to facilitate describing, in the present disclosure, the first fitting component 31 fits with the second fitting component 41 in the locked state via magnetic attraction that is taken an example to illustrate.

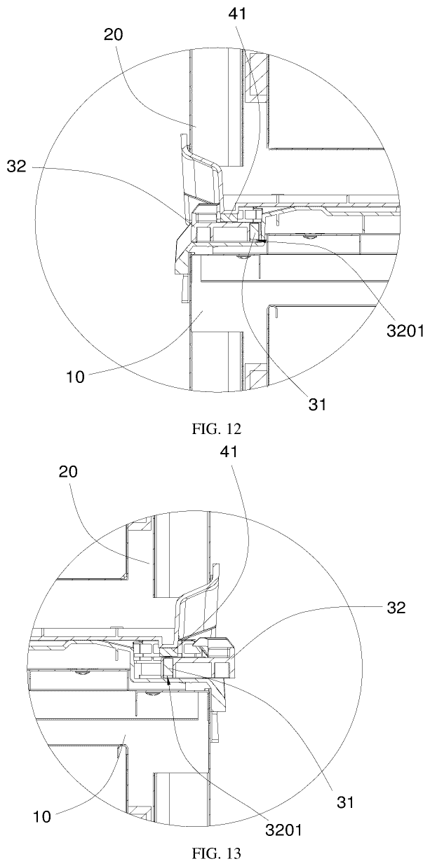

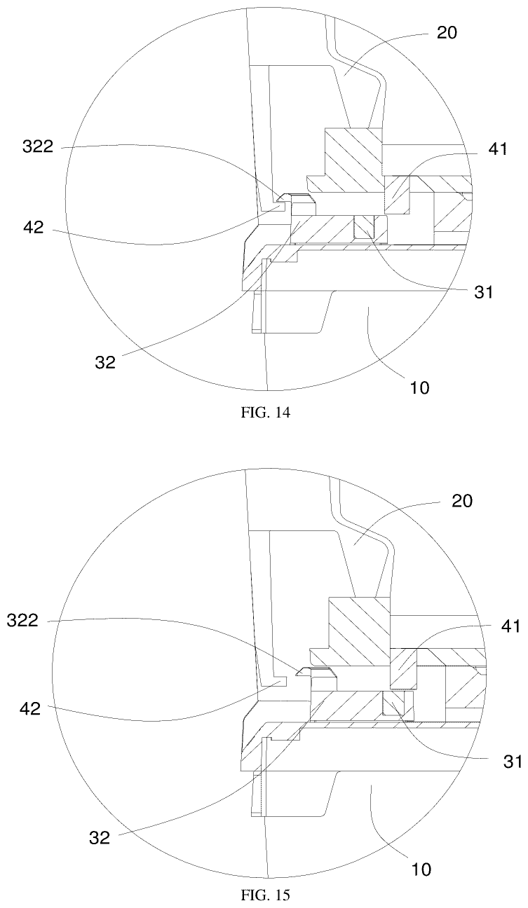

When the first movable component 32 drives the first snapping portion 322 to move away from the center of the first stacking device 10 by the external force, thereby releasing a snap between the first snapping portion 322 and the second snapping portion 42 and forming the unlocked state, i.e., when the first movable component 32 slides outwards when being pulled by the external force, a snapping direction of the first snapping portion 322 is required to be configured as a direction along the Y direction towards the center of the first stacking device 10. Based on this, referring to FIGS. 12 and 13, one end of the first snapping portion 322 is connected to the seat 321, and the other end of the first snapping portion 322 extends towards the center of the first stacking device 10, thereby snapping the first snapping portion 322 with the second snapping portion 42. A position of the second snapping portion 42 corresponds to the first snapping portion 322, which is not described in detail herein.

In the present embodiment, the first snapping portion 322 is disposed on a side of the first fitting component 31 away from the center of the first stacking device 10, and the first snapping portion 322 extends from a side of the seat 321 away from the center of the first stacking device 10 to a direction towards the center of the first stacking device 10. Since the first fitting component 31 and the second fitting component 41 are in the unlocked state, the first fitting component 31 fits with the second fitting component 41 via magnetic attraction, the first elastic component 33 is in a compressed state, and the first elastic component 33 remains in the compressed state due to magnetic attraction.

Similarly, in another embodiment, when the first movable component 32 drives the first snapping portion 322 to move towards the center of the first stacking device 10 by the external force, thereby releasing the first snapping portion 322 from the second snapping portion 42 and forming the unlocked state, i.e., when the first movable component 32 slides inwards when being pulled inwards by the external force, the snapping direction between the first snapping portion 322 and the second snapping portion 42 is required to be configured as a direction along the Y direction and away from the center of the first stacking device 10. Based on this, referring to FIGS. 14 and 15, one end of the first snapping portion 322 is connected to the seat 321, and the other end of the first snapping portion 322 extends away from the center of the first stacking device 10, thereby snapping the first snapping portion 322 with the second snapping portion 42.

The first snapping portion 322 is disposed on the side of the first fitting component 31 away from the center of the first stacking device 10, and the first snapping portion 322 extends from the side of the seat 321 away from the center of the first stacking device 10 to a direction away from the center of the first stacking device 10. Since the first fitting component 31 and the second fitting component are in the unlocked state, the first fitting component 31 fits with the second fitting component 41 via magnetic attraction, the first elastic component 33 is in a stretching state, the first elastic component 33 remains in the stretching state due to magnetic attraction. The first fitting structure 30 is released from the second fitting structure 40 by pulling the first movable component 32 that is taken to illustrate herein.

In an embodiment, referring to FIGS. 12 to 15, the seat 321 is provided with an assembly groove 3201, the first fitting component 31 is accommodated in the assembly groove 3201. Therefore, the first fitting component 31 can be mounted on the first movable component 32. The assembly groove 3201 may be disposed on a middle portion of the seat 321 or symmetrically disposed on the seat 321. Alternatively, the assembly groove 3201 may be disposed on the first snapping portion 322. The number of the assembly groove 3201 may be one or more.

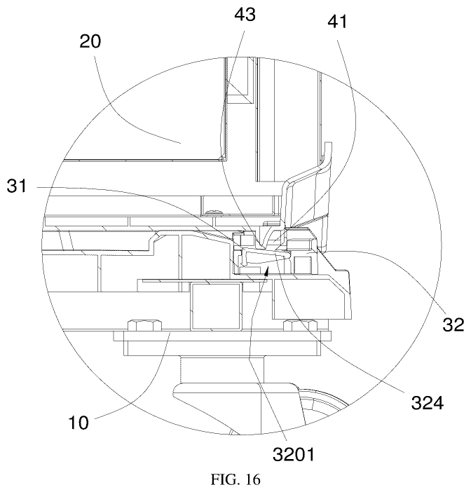

In another embodiment, referring to FIGS. 16 to 19, the first movable component 32 further includes a locating block 324. The seat 321 is provided with an assembly groove 3201, the locating block 324 is mounted in the assembly groove 3201 and movably connected to the seat 321. Furthermore, at least part of the locating block 324 can protrude from the assembly groove 3201. A first fitting component 31 is defined by at least part of the locating block 324. Alternatively, the first fitting component 31 is mounted on the locating block 324. Therefore, the first fitting component 31 attracts with the second fitting component 41 in the unlocked state.

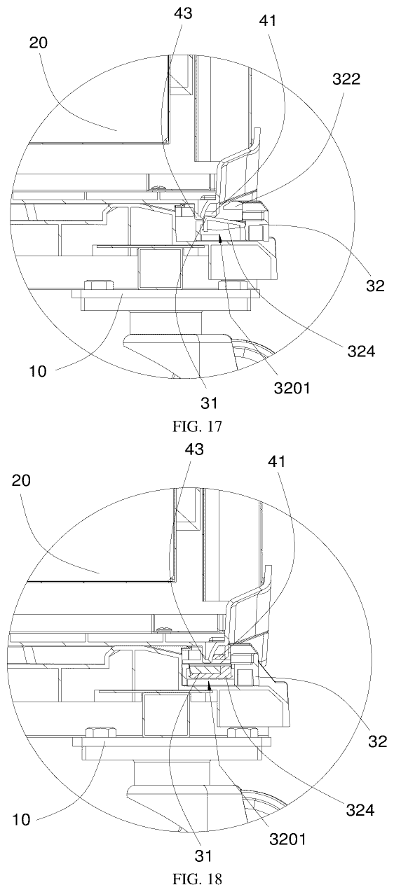

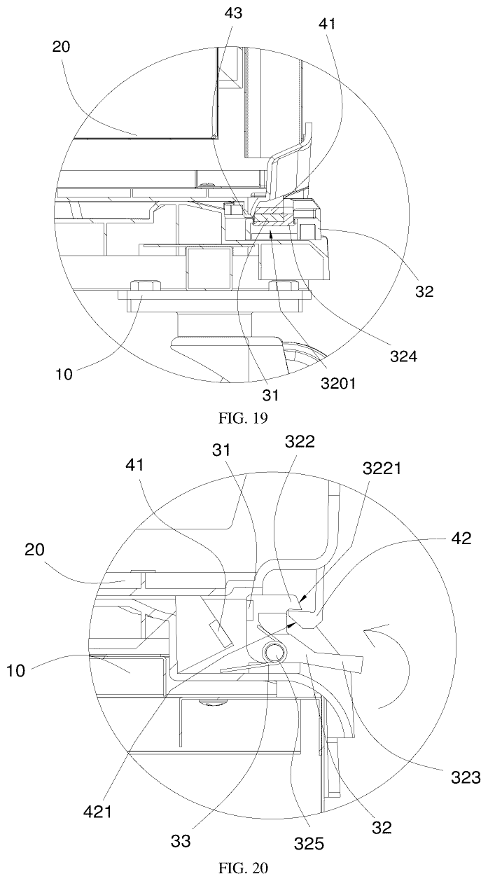

A movement manner of the locating block 324 moving in the assembly groove 3201 can be shown as FIGS. 16 and 17. The locating block 324 is rotatably connected to the seat 321 via an end of the locating block 324. The locating block 324 is in linear contact with or in surface contact with the second fitting component 41. Alternatively, referring to FIGS. 18 and 19, the locating block 324 movably fits with an inner wall of the assembly groove 3201 in a guiding manner. The locating block 324 is in surface contact with the second fitting component 41, thereby ensuring a contact area between the locating block 324 and the second fitting component 41, and improving reliably of magnetic attraction. Therefore, the locating block 324 can move along the Z direction, resulting in the first fitting component 31 fitting with the second fitting component 41.

Furthermore, referring to FIGS. 16 to 19, the second fitting structure 40 further includes a stop portion 43 disposed on the second stacking device 20. The stop portion 43 can be disposed towards the second fitting component 41. When the first fitting component 31 fits with the second fitting component 41 via magnetic attraction, at least part of the locating block 324 is stopped by the stop portion 43, such that a movement of the first movable component 32 is limited and the first movable component 32 is positioned, and the phenomenon that the first elastic component 33 drives the first movable component 32 to move can be avoided. Therefore, an effect of positioning the first elastic component 33 is more reliable.

In an embodiment, referring to FIG. 43, the first fitting structure 30 further includes a gear 34, a transmission plate 35 and a third rotating shaft 36. The first fitting component 31, the gear 34, the transmission plate 35 and the third rotating shaft 36 are all mounted in the seat 321. The first fitting component 31 is connected to a periphery side of the third rotating shaft 36 and can rotate around an axis of the third rotating shaft 36. An end of the third rotating shaft 36 away from the first fitting component 31 penetrates through and is connected to the gear 34. One end of the transmission plate 35 is connected to the gear in a transmission manner, and at least part of the other end of the transmission plate 35 protrudes from an outer surface of the seat 321. When the first fitting component 31 and the second fitting component 41 are in the locked state, the first fitting component 31 fits with the second fitting component 41 via magnetic attraction. When the first fitting structure 30 is required to be released from the second fitting structure 40, the transmission plate 35 can move by the external force and drive the gear 34, the third rotating shaft 36 and the first fitting component 31 to rotate, such that the first fitting component 31 rotates away from the second fitting component 41. For example, the first fitting component 31 can rotate with a degree of 90°, 180° and so on, then there is no magnetic attraction between the first fitting component 31 and the second fitting component 41; alternatively, magnetic attraction between the first fitting component 31 and the second fitting component 41 is reduced to a certain extent, thereby avoiding a movement of the first fitting component 31 the second fitting component 32 from being effected by magnetic attraction affecting.

This is, in the present embodiment, when the first fitting structure 30 is released from the second fitting structure 40, the first fitting component 31 is driven to rotate by the gear in a transmission manner, such that magnetic attraction between the first fitting component 31 and the second fitting component 41 is lower, facilitating releasing the first fitting structure 30 from the second fitting structure 40.

Moreover, when the first fitting structure 30 and the second fitting structure 40 are in the locked state, the first elastic component 33 deforms, such that the first elastic component 33 has a tendency of driving the first snapping portion 322 to move away from the second snapping portion 42. Therefore, when the magnetic force between the first fitting component 31 and the second fitting component 41 is less than the elastic force of the first elastic component 33, the seat 321 can automatically eject, thereby releasing the first fitting component 31 from the second fitting component 41. Therefore, the first fitting structure 30 is released from the second fitting structure 40. Alternatively, the first elastic component 33 is not required to be provided, the first fitting component 31 can be released from the second fitting component 41 by manually pulling. In addition, as required, the second fitting structure 40 can drive the second fitting component 41 to rotate by the gear in the transmission manner that is the similar as the first fitting structure 30.

In the present disclosure, a second embodiment of cooperation between the first fitting structure 30 and the second fitting structure 40 is introduced hereinafter.

The structure and the concept of the present embodiment is substantially the same as that of the first embodiment, similarities thereof will not be repeated, and the difference is in that: in the second embodiment, referring to FIGS. 20 to 23, the first movable component 32 is provided with a first rotating shaft 325, the first movable component 32 is rotatably connected to the first stacking device 10 via the first rotating shaft 325. That is, in the second embodiment, the first movable component 32 is rotating. Therefore, the first movable component 32 can move easily and quickly relative to the first stacking device 10.

Furthermore, the first elastic component 33 is configured as a torsional spring. The first elastic component 33 is sleeved on a periphery of the first rotating shaft 325, and abuts against the first movable component 32 and the first stacking device 10, thereby applying a force to the first movable component 32. Therefore, the first movable component 32 may apply a force to the torsional spring when the first movable component 32 rotates by the external force, such that the torsional spring suffers from a force and deforms. When the first movable component 32 rotates to a certain position, the first fitting component 31 and the second fitting component 41 fit with each other and are positioned via magnetic attraction. After the second stacking device 20 detaching from the first stacking device 10, the magnetic force remaining the torsional spring to deform disappears, such that the torsional spring can drive the first movable component 32 to automatically reset.

Similarly, in the present embodiment, the first movable component 32 has two rotating directions, i.e., the first movable component 32 can rotate towards or away from the center of the first stacking device 10.

When the first movable component 32 drives the first snapping portion 322 towards the center of the first stacking device 10 by the external force, the first snapping portion 322 is released from the second snapping portion 42, thereby forming the unlocked state, i.e., when the first movable component 32 is rotated upwards by the external force, the snapping direction of the first snapping portion 322 and the second snapping portion 42 are required to configured as a direction roughly along the Y direction and away from the center of the first stacking device 10. Based on this, referring to FIGS. 20 and 21, one end of the first snapping portion 322 is connected to the seat 321, and the other end of the first snapping portion 322 extends away from the center of the first stacking device 10, thereby snapping the first snapping portion 322 with the second snapping portion 42.

In the present embodiment, the first snapping portion 322 is disposed on a side of the first fitting component 31 away from the center of the first stacking device 10, and the first snapping portion 322 extends from a side of the seat 321 away from the center of the first stacking device 10 to a direction away from the center of the first stacking device 10.

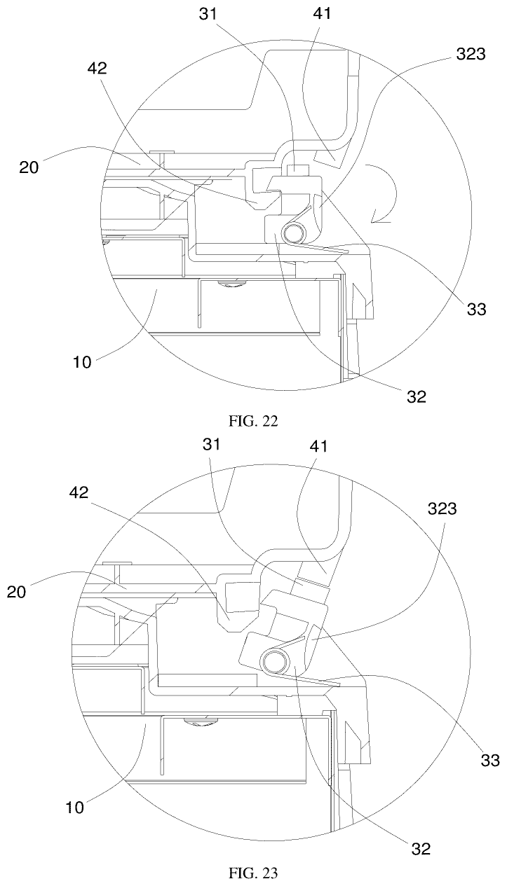

Similarly, in another embodiment, when the first movable component 32 drives the first snapping portion 322 to move away from the center of the first stacking device 10 by the external force to release the first snapping portion 322 from the second snapping portion 42 forming the unlocked state, i.e., when the first movable component 32 is rotated downwards, the snapping direction of the first snapping portion 322 and the second snapping portion 42 is required to be configured as a direction substantially along the Y direction and towards the center of the first stacking device 10. Based on this, referring to FIGS. 22 and 23, one end of the first snapping portion 322 is connected to the seat 321, and the other end of the first snapping portion 322 extends towards the center of the first stacking device 10, thereby snapping the first snapping portion 322 with the second snapping portion 42.

In the present disclosure, the first snapping portion 322 is disposed on a side of the first fitting component 31 towards the center of the first stacking device 10, and the first snapping portion 322 extends from a side of the seat 321 to a direction towards the center of the first stacking device 10 to the center of the first stacking device 10.

In the present disclosure, since the first elastic component 33 is configured as the torsional spring, a structure and mounting direction of the torsional spring are adjusted, such that the first elastic component 33 is not restricted by the magnetic force after the first fitting component 31 being separated from the second fitting component 41. Therefore, the first movable component 32 is driven to move and reset.

In the present disclosure, a third embodiment of cooperation between the first fitting structure 30 and the second fitting structure 40 is introduced hereinafter.

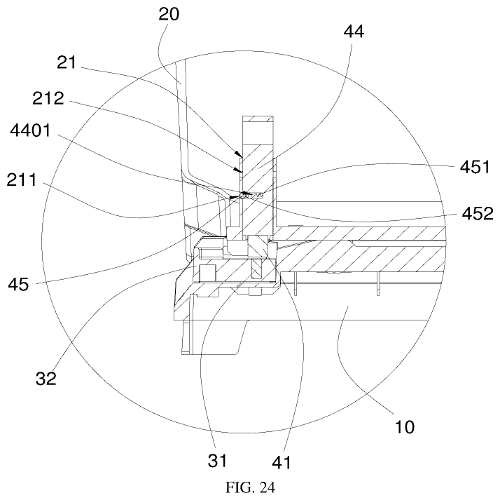

In the present embodiment, the structure and the concept of the present embodiment is substantially the same as that of the first embodiment, similarities thereof will not be repeated, and the difference is in that: in the third embodiment, referring to FIGS. 24 to 33, the first fitting component 31 is mounted on the first movable component 32, the second fitting structure 40 further includes a second movable component 44, the second fitting component 41 is mounted on the second movable component 44, and the second movable component 44 can be movably connected to the second stacking device 20. With a movement of the second movable component 44, the second fitting component 41 can magnetically fit with or be misaligned with the first fitting component 41 to form the locked state or the unlocked state.

In the third embodiment, a magnetic fitting relationship between the first fitting component 31 and the second fitting component 41 is realized when being driven by the first movable component 32 and the second movable component 44, thereby realizing switching the stacking system 100 between the locked state or the unlocked state.

Furthermore, referring to FIGS. 24 to 33, the first movable component 32 is slidably connected to the first stacking device 10, and the second movable component 44 is slidably connected to the second stacking device 20. A sliding direction of the first movable component 32 intersects with a sliding direction of the second movable component 44. The sliding direction of the first movable component 32 intersects with the sliding direction of the second movable component 44, which is conducive to fitting the first fitting component 31 with the second fitting component 41. The sliding direction of the first movable component 32 can be perpendicular to the direction of the second movable component 44, facilitating the second movable component sliding.

The sliding direction of the first movable component 32 is substantially parallel to the Y direction, and an angle is defined between the sliding direction of the second movable component 44 and the sliding direction of the first movable component 32, facilitating the second movable component 44 sliding.

The first fitting component 31 can fit with the second fitting component 41 via magnetic attraction or magnetic repulsion in the locked state. Alternatively, the first fitting component 31 can fit with the second fitting component 41 via magnetic attraction or magnetic repulsion in the unlocked state.

When the first fitting component 31 fits with the second fitting component 41 via magnetic attraction in the locked state, in the locked state, the first fitting structure 30 and the second fitting structure 40 are positioned by the first fitting component 31 and the second fitting structure 41 via magnetic attraction. The first movable component 32 can drive the first snapping portion 322 to move until the first snapping is snapped with the second snapping portion 42 via magnetic attraction. The first elastic component 33 deforms and remains deformation via magnetic attraction. The first elastic component 33 has a tendency of driving the first snapping portion 322 to move away from the second snapping portion 42. This is, the first movable component 32 overcomes the elastic force of the first elastic force via magnetic attraction to snap the first snapping portion 322 with the second snapping portion 42. When the first fitting component 31 is required to be released from the second fitting component 41, the second movable component 44 drives the second fitting component 41 to move until the second fitting component 41 is misaligned with the first fitting component 31 by the external force, the magnetic force between the first fitting component 31 and the second fitting component 41 is gradually reduced, and the first movable component 32 can move to reset by the elastic force of the first elastic component 33, thereby releasing the first snapping portion 322 from the second snapping portion 42.

Since the first fitting component 31 fits with the second fitting component 41 via magnetic attraction, when the second fitting component 41 moves away from the first fitting component 31, magnetic attraction between the first fitting component 31 and the second fitting component 41 is lower, the first movable component 32 can automatically slide and be positioned by the elastic force of the first elastic component 33, thereby forming the unlocked state. Therefore, the first movable component 32 is operated without the external force, and a process of unlocking is simpler.

Furthermore, the first elastic component 33 deforms due to the magnetic force in the locked state, a deformation of the first elastic component 33 can be formed by compressing or stretching. The deformation is formed by compressing that is taken as an example. The first movable component 32 moves toward or away from the center of the first stacking device 10 by changing a connecting end between the first stacking device 10 and the first elastic component 33, respectively.

For example, when the first movable component 32 is required to move towards the first stacking device 10, one end of the first elastic component 33 away from the center of the first stacking device 10 is connected to the first stacking device 10, and the other end of the first elastic component 33 is connected to the first movable component 32. Correspondingly, the snapping direction of the first snapping portion 322 and the second snapping portion 42 is changed. One end of the first snapping portion 322 is connected to the seat 321, the other end of the first snapping portion 322 extends towards the center of the first stacking device 10, i.e., the first snapping portion 322 is snapped with the second snapping portion 42 along a direction away from the center direction of the first stacking device 10. Therefore, the first movable component 32 drives the first snapping portion 322 to slide by the external force, i.e., the first movable component 32 moves towards the center of the first stacking device 10, the second fitting component 41 can move away from the first fitting component 31 to release the first snapping portion 322 from the second snapping portion 42, thereby forming the unlocked state.

The first snapping portion 322 can be disposed on a side of the first snapping portion 31 away from the center of the first stacking device 10, and the first snapping portion 322 extends from a side of the seat 321 away form the center of the first stacking device 10 to a direction away from the center of the first stacking device 10.

In addition, when the first movable component 32 is required to move away from the first stacking device 10, one end of the first elastic component 33 towards the center of the first stacking device 10 is connected to the first stacking device 10, and the other end of the first elastic component 33 is connected to the first movable component 32. Correspondingly, the snapping direction of the first snapping portion 322 and the second snapping portion 42 is changed. One end of the first snapping portion 322 is connected to the seat 321, the other end of the first snapping portion 322 extends towards the center of the first stacking device 10, i.e., the first snapping portion 322 is snapped with the second snapping portion 42 along a direction towards the center direction of the first stacking device 10. The first movable component 32 drives the first snapping portion 322 to slide by the external force, i.e., the first movable component 32 moves away from the center of the first stacking device 10, the second fitting component 41 can move away from the first fitting component 31 to release the first snapping portion 322 from the second snapping portion 42, thereby defining the unlocked state.

The first snapping portion 322 can be disposed on a side of the first snapping portion 31 away from the center of the first stacking device 10, and the first snapping portion 322 extends from a side of the seat 321 away form the center of the first stacking device 10 to a direction towards the center of the first stacking device 10.

When the first elastic component 33 is stretched and deforms in the locked state, it is only required to change the end of the first stacking device 10 connecting to the first elastic component 33 and the end of the first movable component 32 connecting to the first elastic component 33, which is not described in detail herein.

When the first fitting component 31 fits with the second fitting component 41 via magnetic attraction in the unlocked state, the first fitting component 31 is misaligned with the second fitting component 41 in the locked state, magnetic attraction between the first fitting component 31 and the second fitting component 41 is not sufficient, such that the first elastic component 33 can apply a force to the first movable component 32 to insert the first snapping portion 322 into the second snapping portion 42, realizing snapping the first snapping portion 322 with the second snapping portion 42. When the first fitting component 31 is required to be released from the second movable component 41, the second movable component 44 drives the second snapping portion 41 to move towards the first fitting component 31 by the external force, magnetic attraction between the first movable component 32 and the second movable component 44 gradually increases, and the magnetic force overcomes the elastic force of the first elastic component 33 to drive the first movable component 32 to move. Therefore, the first snapping portion 322 is released from the second snapping portion 42. In the unlocked state, the first fitting structure 30 and the second fitting structure 40 can be positioned by the the first fitting component 31 and the second snapping portion 41 via magnetic attraction. The first elastic component 33 deforms and remains the deformation via magnetic attraction, and the first elastic component 33 has a tendency of driving the first snapping portion 322 to move towards the second snapping portion 42. Since the first fitting component 31 fits with the second fitting component 41 via magnetic attraction, after the second fitting component 41 moving towards the first fitting component 31, magnetic attraction between the first fitting component 31 and the second fitting component 41 increases, and the first movable component 32 can automatically slide and be positioned to form the unlocked state. Therefore, the first movable component 32 is operated without the external force, and an unlocking process is simpler.

Furthermore, when first fitting component 31 fits with the second fitting component 41 in the unlocked state via magnetic attraction, a connecting manner of the first elastic component 33 and a position of the first snapping portion 322 are the similar as those when the first fitting component 31 fits with the second fitting component 41 in the locked state via magnetic attraction, it is only required to correspondingly change structures of the first snapping component 322 and the second snapping component 42, which is not described in detail herein.

When the first fitting component 31 fits with the second fitting component 41 via magnetic repulsion in the locked state, in the locked state, the first fitting structure 30 and the second fitting structure 40 can be positioned by the first fitting component 31 and the second fitting component 41 via magnetic repulsion. The first movable component 32 can drive the first snapping portion 322 to move until the first snapping portion 322 is snapped with the second snapping portion 42 via magnetic repulsion, the first elastic component 33 deforms and remains deformation via magnetic repulsion, and the first elastic component 33 has a tendency of driving the first snapping portion 322 to move away from the second snapping portion 42. This is, the first snapping portion 32 overcomes the elastic force of the first elastic component 33 via magnetic repulsion to snap the first snapping portion 322 with the second snapping portion 42. When the first fitting component 31 is required to be released from the second movable component 41, the second movable component 44 drives the second fitting component 41 to move until the second movable component 44 is misaligned with the first fitting component 31 by the external force, magnetic repulsion between the second fitting component 41 and the first fitting component 31 gradually decreases, and the first movable component 32 can move and be reset through the elastic force of the first elastic component 33, thereby releasing the first snapping portion 322 from the second snapping portion 42.

Since the first fitting component 31 fits with the second fitting component 41 via magnetic repulsion, when the second fitting component 41 moves towards the first fitting component 31, magnetic repulsion is lower, and the first movable component 32 can automatically slide and be positioned to define the unlocked state, such that the first movable component 32 is operated without the external force, and the unlocking process is simpler.

Furthermore, when the first fitting component 31 fits with the second fitting component 41 in the locked state via magnetic repulsion, a connecting manner of the first elastic component 33 and a position of the first snapping portion 322 are the similar as those when the first fitting component 31 fits with the second fitting component 41 via magnetic attraction in the locked state, it is only required to correspondingly change the structures of the first snapping component 322 and the second snapping component 42, which is not described in detail herein.

When the first fitting component 31 fits with the second fitting component 41 in the unlocked state via magnetic repulsion, the first fitting component 31 is misaligned with the second fitting component 41 in the locked state, magnetic attraction between the first fitting component 31 and the second fitting component 41 is not sufficient, such that the first elastic component 33 can apply the force to the first movable component 32 to insert the first snapping portion 322 into the second snapping portion 42. Therefore, the first snapping portion 322 is snapped with the second snapping portion 42. When the first fitting component 31 is required to be released from the second movable component 41, the second movable component 44 drives the second snapping portion 41 to move towards the first fitting component 31 by the external force, magnetic attraction between the first movable component 32 and the second movable component 44 gradually increases, and the magnetic force overcomes the elastic force of the first elastic component 33 to move the first movable component 32. Therefore, the first snapping portion 322 is released from the second snapping portion 42. In the unlocked state, the first fitting structure 30 and the second fitting structure 40 can be positioned by the first fitting component 31 and the second snapping portion 41 via magnetic repulsion. The first elastic component 33 deforms and remains the deformation via magnetic attraction, and the first elastic component 33 has a tendency of driving the first snapping portion 322 to move towards the second snapping portion 42.

Since the first fitting component 31 fits with the second fitting component 41 via magnetic repulsion, after the second fitting component 41 moving towards the first fitting component 31, magnetic repulsion between the first fitting component 31 and the second fitting component 41 increases, the first movable component 32 can automatically slide and be positioned to define the unlocked state, the first movable component 32 is operated without the external force, and a process of unlocking is simpler.

Furthermore, when the first fitting component 31 fits with the second fitting component 41 via magnetic repulsion in the unlocked state, a connecting manner of the first elastic component 33 and a position of the first snapping portion 322 are the similar as those when the first fitting component 31 fits with the second fitting component 41 via magnetic attraction in the locked state, it is only required to correspondingly change the structures of the first snapping component 322 and the second snapping component 42, which is not described in detail herein.

The above is a basic principle of the movement of the first fitting structure 30 and the second fitting structure 40 in the present embodiment, based on the this, the present embodiment further provides a plurality of embodiments which is based on the principle, which is described as following.

In an embodiment, referring to FIGS. 24 to 31, the second stacking device 20 is further provided with an assembling hole 21, and the second movable component 44 is movably mounted in the assembling hole 21. The second movable component 44 can slide by the external force to switch the first fitting component 31 and the second fitting component 41 between a fitting state and a unfitting state.

For example, the assembling hole 21 and the second movable component 44 can both extend along the Z direction. The second movable component 44 is mounted in the assembling hole 21, thereby improving moving stability of the second movable component 44. The second fitting component 41 is connected to an end of the second movable component 44 along the Z direction and towards the first movable component 32.

Furthermore, a sliding direction of the second movable component 44 is perpendicular to a sliding direction of the first movable component 32. The second movable component 44 can slide when being pulled or pushed by the external force to switch the first fitting component 31 and the second fitting component 41 between the fitting state or the unfitting state. Therefore, the second movable component 44 can slide simpler.

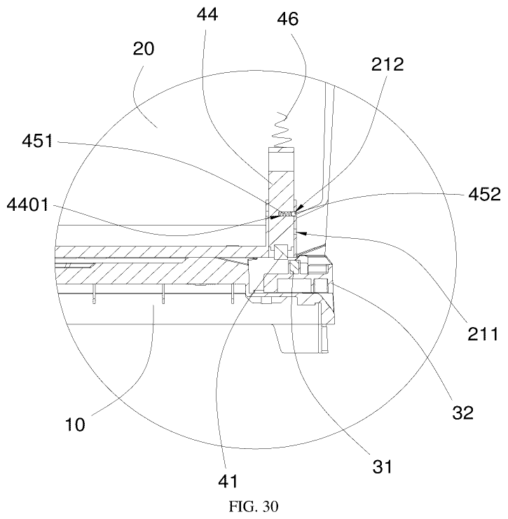

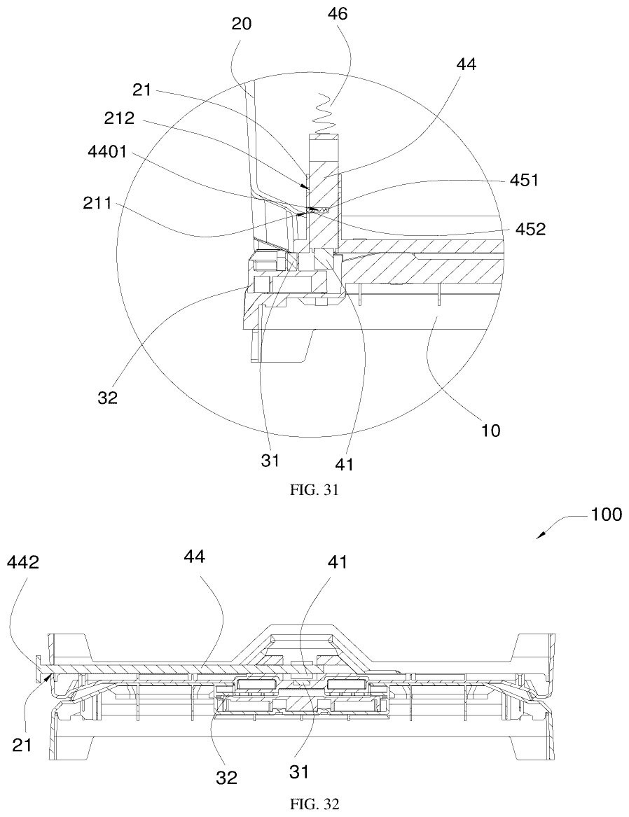

The movement of the second movable component 44 can be linked with an action of transporting the second stacking device 20. When an operator holds the second stacking device 20 with their hands, they can be in contact with the second movable component 44. When the force is applied to extract the second stacking device 20 or a moment before extracting, referring to FIGS. 24 to 29, the operator pulls the second movable component 44, and the second movable component 44 slides upwards to release the first stacking device 10 from the second stacking device 20, thereby smoothly extracting the second stacking device 20. Alternatively, when a force is applied to extract the second stacking device 20, the operator can press the second movable component 44, referring to FIGS. 30 and 31, the second movable component 44 slides downwards to release the first stacking device 10 from the second stacking device 20, thereby smoothly extracting the second stacking device 20.

Referring to FIGS. 24 to 31, a sidewall of the second movable component 44 is provided with an installing hole 4401. The second fitting structure 40 further includes a locating assembly 45, the locating assembly 45 is mounted in the installing hole 4401, and at least part of the locating assembly 45 protrudes from the installing hole 4401 and fits with and is connected to an inner wall of the assembling hole 21. Therefore, it is conducive to positioning the second movable component 44, thereby improving reliably of the second movable component 44.

The locating assembly 45 includes a second elastic component 451 and a ball bearing 452. One end of the ball bearing 452 is connected to the second elastic component 451, and at least part of the other end of the ball bearing protrudes from the installing hole 4401 to fit with and is connected to the inner wall of the assembling hole 21. Therefore, a structure of the locating assembly is simple and easy to process.

Furthermore, referring to FIGS. 24 to 31, the inner wall of the assembling hole 21 is provided with a first fitting position 211 and a second fitting position 212. The first fitting position 211 is disposed on a side of the second fitting position 212 towards the first movable component 32. The first fitting position 211 and the second fitting position 212 corresponds to the locked state and the unlocked state, respectively. When the second movable component 44 drives the locating assembly 45 to move, the ball bearing 452 of the locating assembly 45 can fit with the first fitting position 211 or the second fitting position 212, thereby providing a tactile feedback and ensuring the second movable component 44 to move correctly.

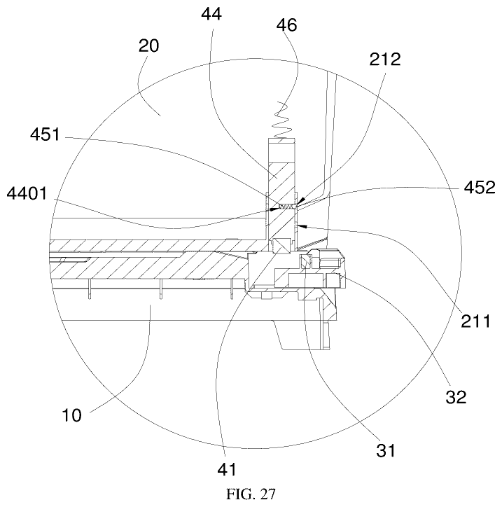

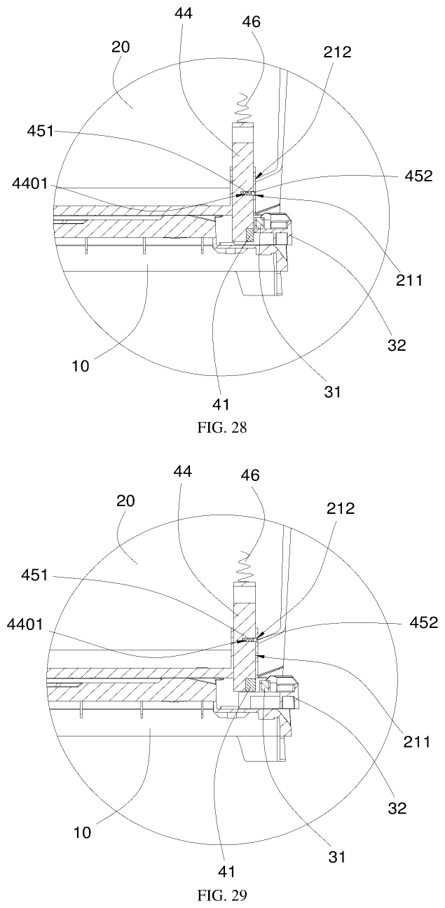

For example, when the second movable component 44 slides upwards and is unlocked by the external force along the Z direction, i.e., when the second movable component 44 is pulled, the second movable component 44 can drive the locating assembly 45 to move from the first fitting position 211 to the second movable component 212. Referring to FIGS. 26 and 27, the first fitting component 31 fits with the second fitting component 41 via magnetic attraction, and the first fitting component 31 attracts with the second fitting component 41 in the locked state. After the second movable component 44 being pulled, the first fitting component 31 and the second fitting component 41 move away from each other, magnetic attraction between the first fitting component 31 and the second fitting component 41 is reduced, and the first movable component 32 ia capable of moving by the first elastic component 33, thereby releasing the first fitting component 31 from the second fitting component 41. Referring to FIGS. 28 and 29, the first fitting component 31 fits with the second fitting component 41 via magnetic repulsion, and the first fitting component 31 is misaligned with the second fitting component 41 in the locked state. After the second movable component 44 being pulled, the first fitting component 31 and the second fitting component 41 move towards each other, magnetic repulsion between the first fitting component 31 and the second fitting component 41 increases, thereby overcoming the elastic force of the first elastic component 33 to push the first movable component 32 to move. Therefore, the first fitting component 31 is released from the second fitting component 41.

When the second movable component 44 slides downwards and is released by the external force along the Z direction, i.e., when the second movable component 44 is pressed, the second movable component 44 can drive the locating assembly 45 to move from the second fitting position 212 to the first fitting position 211. Referring to FIGS. 30 and 31, the first fitting component 31 fits with the second fitting component 41 via magnetic repulsion, the first fitting component 31 is misaligned with the second fitting component 41 in the locked state. After the second movable component 44 being pressed, the first fitting component 31 and the second fitting component 41 move towards each other, magnetic repulsion between the the first fitting component 31 and the second fitting component 41 increases, thereby overcoming the elastic of the first elastic component 33 to drive the first movable component 32 to move and releasing the first fitting component 31 from the second fitting component 41. Alternatively, the first fitting component 31 can fit with the second fitting component 41 via magnetic attraction, and the first fitting component 31 attracts with the second fitting component 41 in the locked state. After the second movable component 44 being pressed, the first fitting component 31 and the second fitting component 41 move away from each other, magnetic attraction between the first fitting component 31 and the second fitting component 41 is reduced, the first movable component 32 is moved by the first elastic component 33. therefore, the first fitting component 30 is released from the second fitting structure 40.

The first fitting position 211 and the second fitting position 212 can be configured as a hole or a groove fitting with the ball bearing 452.

Referring to FIGS. 26 to 31, the second fitting structure 40 further includes a third elastic component 46. The third elastic component 46 is connected to an end of the second movable component 44 away from the first movable component 32. The second movable component 44 can slide upwards or downwards along the Z direction by the external force, the third elastic component 46 can deform by the external force, such that the third elastic component 46 has a tendency of driving the second movable component 44 to move and reset. The second movable component 44 can be automatically reset by providing a third elastic component 46 after the action of extracting is finished, which is not required to manual reset, thereby further improving a convenience of operating.

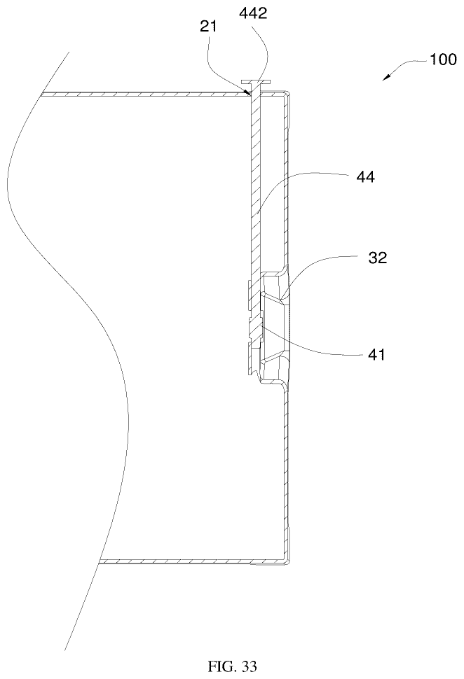

In another embodiment, referring to FIGS. 32 and 33, the assembling hole 21 extends along the X direction. The second movable component 44 is configured as a shaft. The second movable component 44 is movably connected to the second stacking device 20. At least part of the second stacking device 44 protrudes from the second stacking device 20. It is easy to move the second fitting component 41 by the shaft. The second fitting component 41 is connected to a periphery side of the second movable component 44.

Furthermore, the second movable component 44 can slide inwards or outwards along the X direction by the external force, such that the first fitting component 31 and the second fitting component 41 can be switched between the fitting state and the unfitting state.

For example, the second movable component 44 can slide inwards along the X direction by the external force, i.e., the second fitting component 41 moves away from the first fitting component 31 when being pulled by the external force, such that the second fitting component 41 and the first fitting component 31 are switched from the fitting state to the unfitting state. Therefore, the first fitting structure 30 and the second fitting structure 40 are switched from the locked state to the unlocked state. Alternatively, the second movable component 44 can slide outwards along the X direction by the external force, i.e., the second fitting component 41 moves away from the first fitting component 31 when being pulled by the external force, such that the second fitting component 41 and the first fitting component 31 are switched from the fitting state to the unfitting state. Therefore, the first fitting structure 30 and the second fitting structure 40 are switched from the locked state to the unlocked state. The first fitting component 31 fits with the second fitting component 41 via magnetic attraction that is taken as an example herein. However, when the first fitting component 31 fits with the second fitting component 41 via magnetic repulsion, as long as manners of pulling and pressing are correspondingly changed.

Furthermore, referring to FIGS. 24, 25, 32 and 33, the first fitting component 31 can be disposed on a side portion of the second fitting component 41 along the Z direction. Alternatively, the first fitting component 31 can be shown as FIGS. 26 to 31. The first fitting component 31 is disposed on a side portion of the second fitting component 41 along the Y direction. Therefore, the first fitting component 31 relative to the second fitting component 41 can switch between the fitting state or the unfitting state.

In the present disclosure, a fourth embodiment of cooperation between the first fitting structure 30 and the second fitting structure 40 is introduced herein.

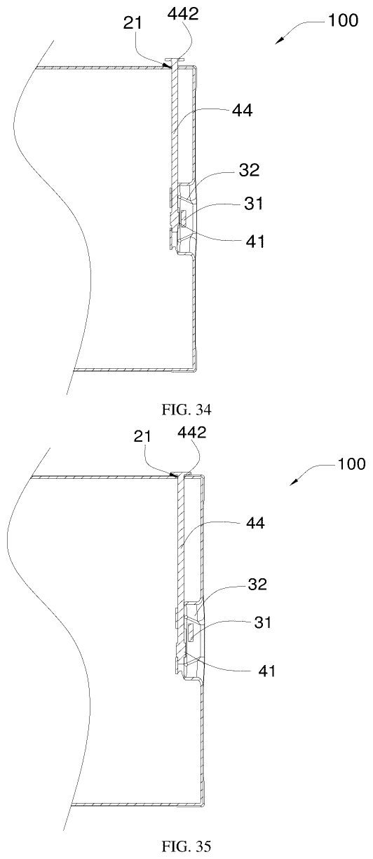

In the present embodiment, the structure and the concept of the present embodiment is substantially the same as that of the first embodiment, similarities thereof will not be repeated, and differences thereof are as follows: referring to FIGS. 34 to 42, in the present embodiment, the second movable component 44 is rotatably connected to the second stacking device 20. The second movable component 44 can be configured as a shaft in the third embodiment. The second movable component 44 is threadedly connected to the second stacking device 20, and at least part of the second movable component 44 protrudes from the second stacking device 20. An axis direction of the second movable component 44 is perpendicular to the sliding direction of the first movable component 32.

That is, referring to FIGS. 34 and 35, when the second movable component 44 rotates, the second movable component 44 can move along the axis direction by thread, such that the second fitting component 41 is driven to move towards or away from the first fitting component 31, which is reasonably provided according to magnetic attraction or magnetic repulsion manner. Therefore, the stacking system can be locked or unlocked.

Furthermore, the second movable component 44 in the present embodiment and the third embodiment is shown as FIGS. 32 to 35. A part of the second movable component 44 protruding from the second stacking device 20 is provided with an applying-force end 442. The applying-force end 442 is configured to provide a applying-force position, which is conducive for the operator pulling or pushing the second movable component 44.

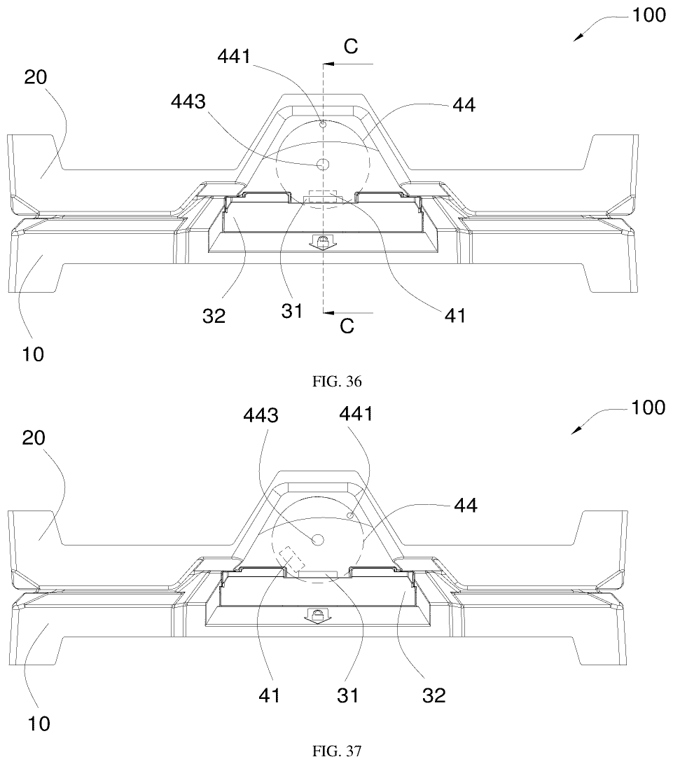

It is not limited by above embodiment, in another embodiment, referring to FIGS. 36, 37, 39 and 40, the second movable component 44 can be configured as a turning disc. The second movable component 44 is provided with a second rotating shaft 443. The second rotating shaft 44 can rotate around an axis of the second rotating shaft 443. An axis direction of the second rotating shaft 443 is the same as the sliding direction of the first movable component 32. It is conducive for the second fitting component 41 fitting with the first fitting component 31 by rotating the turning disc to drive the second fitting component 41 to rotate relative to the first fitting component 31.

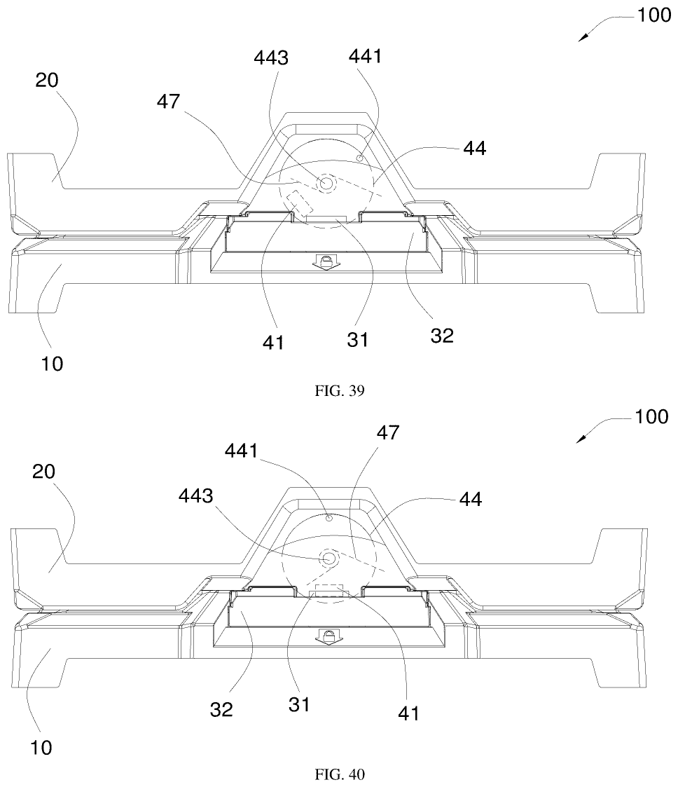

In the locked state, when the second fitting component 41 and the first fitting component 31 are positioned in magnetic attraction manner, in order to realize that the second movable component 44 is automatically reset after extracting, referring to FIGS. 39 and 40, the second fitting structure 40 further includes a fourth elastic component 47. The fourth elastic component 47 is configured as a torsional spring. The fourth elastic component 47 is sleeved on outer circumference of the second rotating shaft 443. The fourth elastic component is connected to the second movable component 44 and the second stacking device 20.

Referring to FIGS. 36 to 42, the second movable component 44 is provided with a second actuation portion 441. The second actuation portion 441 is configured to provide the applying-force position to make the second movable component to rotate. Therefore, it is conducive to rotating of the second movable component 44.

The second actuation portion 441 can be configured as any one of the protrusion, the recess or the knurling, the structure of the second actuation portion 441 is simple and easy to process.

Furthermore, referring to FIGS. 33, 34, 38, 41 and 42, the first fitting component 31 is disposed on a side portion of the second fitting component 41 along the Y direction or the Z direction. Therefore, the first fitting component 31 can rotate relative to the second fitting component 41, thereby switching the first fitting component 41 and the second fitting component between the fitting state and the unfitting state.

The second movable component 44 can be configured as the shaft or the turning disc.

The various technical features of the above embodiments can be combined in any way. In order to make the description concise, not all possible combinations of the various technical features in the above embodiments have been described. However, as long as there is no contradiction in the combination of these technical features, they should be considered within the scope of the specification.

The above embodiments only express several embodiments of the present disclosure, and their descriptions are more specific and detailed, but should not be understood as limiting the scope of the disclosure. It should be pointed out that for ordinary skill in the art, several modifications and improvements can be made without departing from the concept of the disclosure, which are within the scope of protection of the disclosure. Therefore, the scope of protection of the present disclosure should be based on the attached claims.

What is claimed is:

1. A stacking system comprising a first stacking device and a second stacking device, wherein the first stacking device and the second stacking device are stacked along a Z direction, the first stacking device is provided with a first fitting structure, the second stacking device is provided with a second fitting structure; and
the first fitting structure and the second fitting structure each have a locked state and an unlocked state, when the first fitting structure and the second fitting structure are in the locked state, the first fitting structure and the second fitting structure are locked with each other to connect the first stacking device with the second stacking device; when the first fitting structure and the second fitting structure are in the unlocked state, the first fitting structure is capable of being released from the second fitting structure;
wherein the first fitting structure and the second fitting structure are capable of being locked with each other or being released from each other via a magnetic force.

2. The stacking system of claim 1, wherein the first fitting structure comprises a first fitting component, the second fitting structure comprises a second fitting component, and the first fitting component fits with the second fitting component via magnetic attraction or magnetic repulsion.

3. The stacking system of claim 2, wherein the first fitting structure further comprises a first movable component, the first movable component is movably connected to the first stacking device; and
the first fitting component is mounted on the first movable component.

4. The stacking system of claim 3, wherein the first movable component comprises a seat and a first snapping portion disposed on the seat, the seat is movably connected to the first stacking device; and
the second fitting structure comprises a second snapping portion disposed on the second stacking device, the first snapping portion is capable of being inserted into and fitting with the second snapping portion to form the locked state.

5. The stacking system of claim 4, wherein the second fitting component is mounted on the second stacking device, and the first fitting component fits with the second fitting component via magnetic attraction.

6. The stacking system of claim 5, wherein one end of the first snapping portion is connected to the seat, and the other end of the first snapping portion extends towards or away from a center of the first stacking device;
wherein the first movable component is capable of driving the first snapping portion to move by an external force to release the first snapping portion from the second snapping portion to form the unlocked state;
when the first fitting component fits with the second fitting component via magnetic attraction in the locked state, the first fitting structure and the second fitting structure are capable of being positioned by the first fitting component and the second fitting component via magnetic attraction;
when the first fitting component fits with the second fitting component through magnetic attraction in the unlocked state, the first fitting structure and the second fitting structure are capable of being positioned by the first fitting component and the second fitting component via magnetic attraction.

7. The stacking system of claim 6, wherein the first fitting structure further comprises a first elastic component, the first elastic component is connected to both the first movable component and the first stacking device to apply a force to the first movable component;
when the first fitting component fits with the second fitting component via magnetic attraction in the locked state, the first elastic component has a tendency of driving the first snapping portion to move away from the second snapping portion; and
when the first fitting component fits with the second fitting component through magnetic attraction in the unlocked state, the first elastic component has a tendency of driving the first snapping portion to move towards the second snapping portion.

8. The stacking system of claim 5, wherein the first movable component is slidably connected to the first stacking device along a Y direction; and
the first fitting component fits with the second fitting component via magnetic attraction along the Z direction.

9. The stacking system of claim 8, wherein the seat is provided with an assembly groove, the first fitting component is disposed in the assembly groove;
or the first movable component further comprises a locating block, the seat is provided with an assembly groove, the locating block is disposed in the assembly groove and movably connected to the seat, at least part of the locating block is capable of protruding from the assembly groove;
wherein the first fitting component is defined by at least part of the locating block, or the first fitting component is disposed on the locating block.

10. The stacking system of claim 9, wherein an end of the locating block is rotatably connected to the seat, or the locating block movably fits with an inner wall of the assembly groove in a guiding manner.

11. The stacking system of claim 5, wherein the first movable component is provided with a first rotating shaft, and the first movable component is rotatably connected to the first stacking device via the first rotating shaft.

12. The stacking system of claim 6, wherein the first fitting structure further comprises a gear, a transmission plate and a third rotating shaft, the first fitting structure, the gear, the transmission plate and the third rotating shaft are all mounted in the seat;
wherein the first fitting component is connected to a periphery side of the third rotating shaft and capable of rotating around an axis of the third rotating shaft, an end of the third rotating shaft away from the first fitting component penetrates through the gear; one end of the transmission plate is connected to the gear in a transmission manner, at least part of the other end of the transmission plate penetrates through an outer surface of the seat;
when the first fitting component and the second fitting component are in the locked state, the first fitting component fits with the second fitting component via magnetic attraction; and
when the first fitting component and the second fitting component are in the unlocked state, the transmission plate is capable of moving by the external force and driving the gear, the third rotating shaft and the first fitting component to move, such that the first fitting component rotates away from the second fitting component.

13. The stacking system of claim 4, wherein the second fitting structure further comprises a second movable component, the second fitting component is disposed on the second movable component, the second movable component is movably connected to the second stacking device; and
wherein with a movement of the second movable component, the second fitting component is capable of magnetically fitting with or being misaligned with the first fitting component to form the locked state or the unlocked state, respectively.

14. The stacking system of claim 13, wherein one end of the first snapping portion is connected to the seat, the other end of the first snapping portion extends towards or away from a center of the first stacking device;
wherein when the second fitting component moves away from the first fitting component, the first movable component is capable of driving the first snapping portion to move by an external force to release the first snapping portion from the second snapping portion to form the unlocked state;
when the first fitting component fits with the second fitting component via magnetic attraction in the locked state, the first fitting structure and the second fitting structure are positioned by the first fitting component and the second fitting component via magnetic attraction;
when the first fitting component fits with the second fitting component via magnetic attraction in the unlocked state, the first fitting structure and the second fitting structure are positioned by the first fitting component and the second fitting component via magnetic attraction;
when the first fitting component fits with the second fitting component via magnetic repulsion in the locked state, the first fitting structure and the second fitting structure are capable of being locked with each other by the first fitting component and the second fitting component via magnetic repulsion; and
when the first fitting component fits with the second fitting component via magnetic repulsion in the unlocked state, the first fitting structure and the second fitting structure are capable of being released from each other by the first fitting component and the second fitting component via magnetic repulsion.

15. The stacking system of claim 14, wherein the first fitting structure further comprises a first elastic component, the first elastic component is connected to the first movable component and the first elastic component is connected to the first stacking device to apply a force to the first movable component;
when the first fitting component fits with the second fitting component via magnetic attraction in the locked state, the first fitting component has a tendency of driving the first snapping portion to move away from the second snapping portion;
when the first fitting component fits with the second fitting component via magnetic attraction in the unlocked state, the first elastic component has a tendency of driving the first snapping portion to move towards the second snapping portion;
when the first fitting component fits with the second fitting component via magnetic repulsion in the locked state, the first elastic component has a tendency of driving the first snapping portion to move away from the second snapping portion; and
when the first fitting component fits with the second fitting component via magnetic repulsion in the unlocked state, the first elastic component has a tendency of driving the first snapping portion to move towards the second fitting component.

16. The stacking system of claim 13, wherein the first movable component is slidably connected to the first stacking device, the second movable component is slidably connected to the second stacking device; and
wherein the first movable component is capable of sliding substantially along the Y direction, an angle is defined between a sliding direction of the second movable component and a sliding direction of the first movable component.

17. The stacking system of claim 16, wherein the second stacking device is provided with an assembling hole, and the second stacking device is movably mounted in the assembling hole;
wherein the second movable component is capable of sliding by the external force to switch the first fitting component and the second movable component between a fitting state and a unfitting state.

18. The stacking system of claim 17, wherein the assembling hole extends along the Z direction, the second fitting structure further comprises a third elastic component, the third elastic component is connected to an end of the second movable component away from the first movable component, the second movable component is capable of sliding upwards or downwards along the Z direction by the external force, the third elastic component is capable of deforming by the external force, such that the third elastic component has a tendency of driving the second movable component to move and reset;
or the assembling hole extends along the X direction, the second movable component is configured as a shaft, the second movable component is movably connected to the second stacking device, at least part of the second movable component protrudes from the second stacking device; wherein the second movable component is capable of sliding inwards or outwards along the X direction by the external force to switch the first fitting component and the second movable component between the fitting state and the unfitting state.

19. The stacking system of claim 13, wherein the first movable component is slidably connected to the first stacking device, and the second movable component is rotatably connected to the second stacking device.

20. The stacking system of claim 19, wherein the second movable component is configured as a turning disc, the second movable component is provided with a second rotating shaft, the second rotating shaft is capable of rotating around the second rotating shaft, an axis direction of the second rotating shaft is the same as a sliding direction of the first movable component;
or the second movable component is configured as a shaft, the second movable component is threadedly connected to the second stacking device, at least part of the second movable component protrudes from the second stacking device; wherein an axis direction of the second movable component is perpendicular to a sliding direction of the first movable component.

21. The stacking system of claim 1, wherein the first stacking device is provided with a third fitting structure, the third fitting structure is disposed on a positive side of the first fitting structure relative to the first fitting structure along the Y direction or the X direction;
the second stacking device is provided with a fourth fitting structure, the fourth fitting structure is disposed on a positive side of the second stacking device relative to the second fitting structure along the Y direction or the X direction; and
wherein the third fitting structure fits with and is connected to the fourth fitting structure, and when the third fitting structure fits with the fourth fitting structure and the first fitting structure fits with the second fitting structure, movement of the first stacking device and the second stacking device is limited at least along the Z direction.

22. The stacking system of claim 21, wherein the third fitting structure is the same as the first fitting structure, and the fourth fitting structure is the same as the second fitting structure;
or one of the third fitting structure and the fourth fitting structure is configured as a hook, and the other one of the third fitting structure and the fourth fitting structure is configured as a groove, wherein the hook is inserted into the groove to restrict movement of the second stacking device at least along the Z direction.

23. The stacking system of claim 21, wherein one of the first stacking device and the second stacking device protrudes along the Z direction to define a limiting protrusion; the other one of the first stacking device and the second stacking device is recessed to define a limiting groove along the Z direction; and
the limiting protrusion is inserted into the limiting groove to limit the first stacking device moving along the X direction and the Y direction relative to the second stacking device.

24. The stacking system of claim 1, wherein the first fitting structure and the second fitting structure are at a locked position when being in the locked state and at a released position when being in the unlocked state, the first fitting structure and the second fitting structure are located at the released position and/or the locked position via the magnetic force; and
the first fitting structure and the second fitting structure are located at the released position via the magnetic force, such that at least part of the first stacking device is capable of being released and separated from the second stacking device, when the first stacking device is separated from the second stacking device and the magnetic force between the first fitting structure and the second fitting structure is reduced or disappeared, one of the first fitting structure and the second fitting structure is capable of being reset to the locked position; and when the first stacking device is stacked with the second stacking device via gravity of the first stacking device or an external force, the first fitting structure and the second fitting structure are capable of being automatically locked with each other.

25. The stacking system of claim 1, wherein one of the first fitting structure and the second fitting structure is provided with a magnet, the other one of the first fitting structure and the second fitting structure is provided with a ferromagnet;
or the first fitting structure and the second fitting structure are each provided with a magnet; or the first fitting structure and/or the second fitting structure is provided with an electromagnet.

26. The stacking system of claim 25, wherein the first fitting structure comprises a first fitting component, the second fitting structure comprises a second fitting component, the first fitting component and/or the second fitting component is configured as the electromagnet, the stacking system further comprises a controlling module, the controlling module is electrically connected to the first fitting component, which is configured for controlling a magnetic state and a non-magnetic state of the first fitting component;
and/or the controlling module is electrically connected to the second fitting component, which is configured for controlling a magnetic state and a non-magnetic state of the second fitting component.
